(19) United States
(12) Patent Application Publication
(10) Pub. No.: US 2023/0258808 A1
(43) Pub. Date: Aug. 17, 2023

(54) IMAGING ELEMENT AND IMAGING DEVICE

(71) Applicant: Sony Semiconductor Solutions Corporation, Kanagawa (JP)

(72) Inventor: Katsuhiko Hanzawa, Kanagawa (JP)

(21) Appl. No.: 18/015,220

(22) PCT Filed: Jul. 21, 2021
(86) PCT No.: PCT/JP2021/027288

§ 371 Date: Jan. 9, 2023

(30) Foreign Application Priority Data
Jul. 30, 2020 (JP) 2020-129362

(51) Int. Cl. G01S 17/89; H04N 25/77; H04N 25/705; G01S 7/4915

(52) U.S. Cl. CPC G01S 17/89; H04N 25/77; H04N 25/705; G01S 7/4915; H01L 27/14649

(57) ABSTRACT

Imaging elements are disclosed. In one example, first and second photoelectric conversion units perform photoelectric conversion of incident light from an object. A first electric charge transfer unit transfers the electric charges generated by the first photoelectric conversion unit to a first electric charge holding unit. A second electric charge transfer unit transfers the electric charges generated by the first photoelectric conversion unit to a second electric charge holding unit. A third electric charge transfer unit transfers the electric charges generated by the second photoelectric conversion unit to the first electric charge holding unit. A fourth electric charge transfer unit transfers the electric charges generated by the second photoelectric conversion unit to the second electric charge holding unit. Image signals are generated based on the electric charges held in the first and second electric charge holding units.

### FIELD

The present disclosure relates to an imaging element and an imaging device.

### BACKGROUND

An imaging element that images a subject and performs ranging to measure a distance to the subject is used. The distance to the subject can be measured by a time of flight (ToF) method or a method of detecting a phase difference of the subject. The ToF method is a method of emitting light to a subject, detecting reflected light from the subject with an imaging element, and measuring a distance to the subject by clocking time in which the light reciprocates with respect to the subject. Since it is necessary to emit light to the subject, there is a problem that power consumption is large.

On the other hand, ranging by detection of a phase difference of a subject is a method of calculating a position of the subject with respect to a photographing lens and an imaging element on the basis of a focal position of the subject of when the subject is imaged via the photographing lens arranged in front of the imaging element. A phase difference of incident light from the subject is used for this detection of the focal position. When light passing through the photographing lens is divided into two (referred to as pupil division) and two images respectively based on pieces of the divided incident light are generated, a shift amount between the two images corresponds to the phase difference. The focal position of the subject can be detected from this phase difference and a focal length of the photographing lens, and a position to the subject can be measured.

This phase difference can be detected by utilization of a phase difference pixel arranged in the imaging element. The phase difference pixel is a pixel including photoelectric conversion units pupil-divided in a specific direction, and can detect a phase difference in a pupil division direction of the incident light from the subject. As this phase difference pixel, for example, a pixel including a pair of photoelectric conversion units pupil-divided in a lateral direction of an imaging surface of the imaging element can be applied. Since no light source is required, the method of detecting a focus of the subject can reduce power consumption. However, unlike the ToF method, there is a problem that it is difficult to measure a distance of a flat subject such as a wall since it is necessary to detect a phase difference of the subject.

An imaging device using a combination of the ToF method and the method of detecting a phase difference of a subject has been proposed (see, for example, Patent Literature 1). In this imaging device, a photodiode is used as a photoelectric conversion unit, and pixels in which three photodiodes having a rectangular shape in a planar view are arranged are arrayed in a two-dimensional matrix shape. Among the three photodiodes arranged in each of the pixels, a central photodiode is used for the ToF method, and two photodiodes at ends are used for the detection of a phase difference.

### CITATION LIST

### Patent Literature

Patent Literature 1: Japanese Patent Application Laid-open No. 2016-052055

### SUMMARY

### Technical Problem

However, in the above-described conventional technology, since three photodiodes are arranged for each pixel, there is a problem that a configuration of an imaging device becomes complicated.

Thus, the present disclosure proposes an imaging element and an imaging device capable of simplifying a configuration of a pixel.

### Solution to Problem

To solve the problems described above, an imaging element according to an embodiment of the present disclosure includes: a first photoelectric conversion unit and a second photoelectric conversion unit that perform photoelectric conversion of incident light from an object; a first electric charge holding unit and a second electric charge holding unit that hold electric charges generated by the photoelectric conversion; a first electric charge transfer unit that transfers the electric charges generated by the first photoelectric conversion unit to the first electric charge holding unit; a second electric charge transfer unit that transfers the electric charges generated by the first photoelectric conversion unit to the second electric charge holding unit; a third electric charge transfer unit that transfers the electric charges generated by the second photoelectric conversion unit to the first electric charge holding unit; a fourth electric charge transfer unit that transfers the electric charges generated by the second photoelectric conversion unit to the second electric charge holding unit; and a signal generation unit that generates an image signal based on the electric charges held in the first electric charge holding unit and an image signal based on the electric charges held in the second electric charge holding unit.

### BRIEF DESCRIPTION OF DRAWINGS

FIG. 1 is a view illustrating a configuration example of an imaging device according to an embodiment of the present disclosure.

FIG. 2 is a view illustrating a configuration example of an imaging element according to the embodiment of the present disclosure.

FIG. 3 is a view illustrating a configuration example of a pixel according to a first embodiment of the present disclosure.

FIG. 4 is a view illustrating a configuration example of a column signal processing unit according to the embodiment of the present disclosure.

FIG. 5 is a plan view illustrating a configuration example of a pixel according to the first embodiment of the present disclosure.

FIG. 6 is a cross-sectional view illustrating the configuration example of the pixel according to the first embodiment of the present disclosure.

FIG. 7 is a view illustrating an example of generation of an image signal according to the embodiment of the present disclosure.

FIG. 8 is a view illustrating an example of generation of an image signal in ranging according to the embodiment of the present disclosure.

FIG. 9 is a view illustrating another example of generation of an image signal in ranging according to the embodiment of the present disclosure.

FIG. 10 is a view illustrating another example of generation of an image signal in ranging according to the embodiment of the present disclosure.

FIG. 11 is a view illustrating another example of generation of an image signal in ranging according to the embodiment of the present disclosure.

FIG. 12 is a view illustrating an example of ranging processing by phase difference detection according to the embodiment of the present disclosure.

FIG. 13 is a view illustrating an example of ranging processing by a ToF method according to the embodiment of the present disclosure.

FIG. 14 is a view illustrating an example of iToF processing according to the embodiment of the present disclosure.

FIG. 15 is a view illustrating an example of ranging processing by a phase difference detection method and the ToF method according to the embodiment of the present disclosure.

FIG. 16 is a view illustrating another example of ranging processing by the phase difference detection method and the ToF method according to the embodiment of the present disclosure.

FIG. 17 is a plan view illustrating a modification example of a pixel according to the first embodiment of the present disclosure.

FIG. 18 is a view illustrating a configuration example of a pixel according to a second embodiment of the present disclosure.

FIG. 19 is a plan view illustrating the configuration example of the pixel according to the second embodiment of the present disclosure.

FIG. 20 is a cross-sectional view illustrating a configuration example of a pixel according to a third embodiment of the present disclosure.

FIG. 21 is a cross-sectional view illustrating a configuration example of a pixel according to a fourth embodiment of the present disclosure.

FIG. 22 is a view for describing the phase difference detection according to the embodiment of the present disclosure.

FIG. 23 is a view for describing the iToF method according to the embodiment of the present disclosure.

### DESCRIPTION OF EMBODIMENTS

In the following, embodiments of the present disclosure will be described in detail on the basis of the drawings. Note that the description will be made in the following order. Note that in each of the following embodiments, overlapped description is omitted by assignment of the same reference sign to the same parts.

1. First Embodiment

2. Second Embodiment

3. Third Embodiment

4. Fourth Embodiment

5. Ranging by phase difference detection

6. Ranging by iToF method

### 1. First Embodiment

[Configuration of Imaging Device]

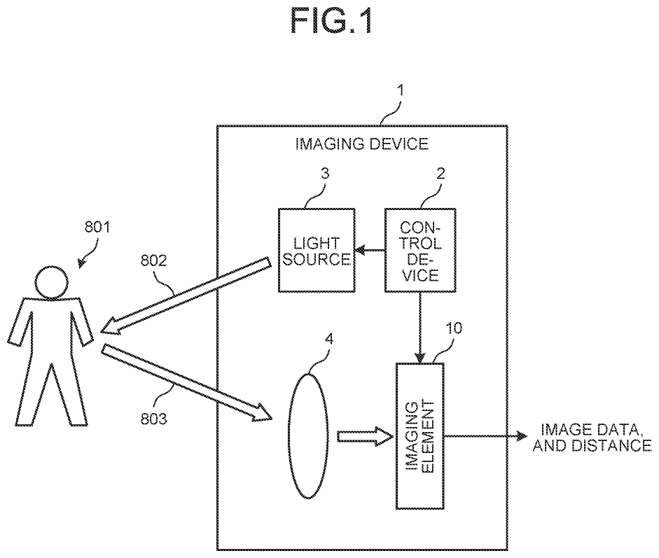

FIG. 1 is a view illustrating a configuration example of an imaging device according to an embodiment of the present disclosure. The drawing is a block diagram illustrating a configuration example of an imaging device 1. The imaging device 1 includes an imaging element 10, a control device 2, a light source 3, and a photographing lens 4. The imaging device 1 images a subject and performs ranging to measure a distance to the subject. The imaging device 1 outputs image data of the subject which image data is generated by imaging, and a distance to an object that is the subject to be a target of distance measurement. An object 801 is further illustrated in the drawing.

The imaging element 10 is a semiconductor element that images the subject. Furthermore, this imaging element 10 performs the ranging with respect to the imaged subject. As described later, the imaging element 10 includes a plurality of pixels that performs photoelectric conversion of incident light from the subject and that generates an image signal.

The light source 3 emits light. This light source 3 emits emission light 802 to the object 801 at the time of the ranging. As the light source 3, for example, a light emitting diode that emits infrared light can be used.

The photographing lens 4 is a lens that forms an image of the subject on a light receiving surface that is a surface on which the pixels of the imaging element 10 are arranged.

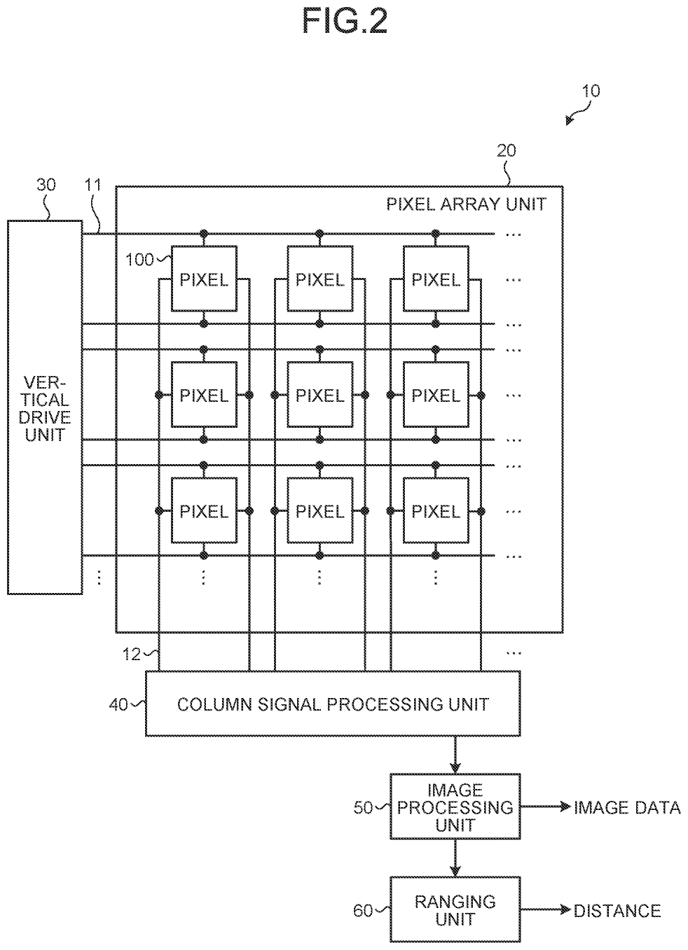

The control device 2 controls the entire imaging device 1. At the time of the ranging, this control device 2 controls the light source 3 to emit the emission light 802 and controls the imaging element 10 to perform the imaging and the ranging. Specifically, the control device 2 controls a vertical drive unit 30, a column signal processing unit 40, a ranging unit 60, and the like (described later in FIG. 2).

At the time of the ranging, the emission light 802 is reflected by the object 801 and reflected light 803 is generated. This reflected light 803 becomes incident on the imaging element 10 via the photographing lens 4 and is detected. Furthermore, time from the emission of the emission light 802 in the light source 3 to the detection of the reflected light 803 in the imaging element 10 is clocked by the imaging element 10, and a distance to the object 801 is calculated. Furthermore, the imaging element 10 further calculates a distance to the object 801 by detecting a phase difference of the incident light from the object 801 and detecting a focal length of the object 801.

[Configuration of Imaging Element]

FIG. 2 is a view illustrating a configuration example of an imaging element according to the embodiment of the present disclosure. The drawing is a block diagram illustrating a configuration example of the imaging element 10. The imaging element 10 includes a pixel array unit 20, the vertical drive unit 30, the column signal processing unit 40, an image processing unit 50, and the ranging unit 60.

The pixel array unit 20 is configured by arrangement of a plurality of pixels 100. The pixel array unit 20 in the drawing represents an example in which the plurality of pixels 100 is arrayed in a shape of a two-dimensional matrix. Here, each of the pixels 100 includes a photoelectric conversion unit that performs photoelectric conversion of the incident light, and generates an image signal of the subject on the basis of the emitted incident light. For example, a photodiode can be used as the photoelectric conversion unit. Signal lines 11 and 12 are wired to each of the pixels 100. Each of the pixels 100 generates the image signal by being controlled by a control signal transmitted by the signal line 11, and outputs the generated image signal via the signal line 12. Note that the signal line 11 is arranged for each row of the shape of the two-dimensional matrix, and is commonly wired to the plurality of pixels 100 arranged in one row. The signal line 12 is arranged for each column of the shape of the two-dimensional matrix, and is commonly wired to the plurality of pixels 100 arranged in one row.

The vertical drive unit 30 generates the control signal of the pixels 100 described above. The vertical drive unit 30 in the drawing can generate the control signal for each row of the two-dimensional matrix of the pixel array unit 20 and perform an output thereof via the signal line 12.

The column signal processing unit 40 processes the image signals generated by the pixels 100. The column signal processing unit 40 in the drawing simultaneously performs processing of the image signals from the plurality of pixels 100 arranged in one row of the pixel array unit 20. As this processing, for example, analog-digital conversion of converting analog image signals generated by the pixels 100 into digital image signals, correlated double sampling (CDS) of removing offset errors of the image signals, or the like can be performed. The processed image signals are output to the image processing unit 50.

The image processing unit 50 processes an image including the image signals output from the column signal processing unit 40. This image processing unit 50 can perform processing with respect to a frame that is the image signals for one screen by all the pixels 100 of the pixel array unit 20. This processing corresponds to, for example, noise reduction processing of reducing noise of the frame. The processed frame is output as image data.

The ranging unit 60 performs ranging of measuring a distance to the subject. This ranging unit 60 measures a distance to an object in the subject. The above-described method of detecting a phase difference of the subject (object) and ToF method can be applied to the measurement of the distance. The ranging unit 60 outputs the measured distance to the outside of the imaging element 10.

In each of the pixels 100 in the drawing, two pupil-divided photoelectric conversion units are arranged, and it is possible to generate phase difference signals that are image signals based on electric charges respectively generated by photoelectric conversion by the photoelectric conversion units. It is possible to detect the focal length of the object from the phase difference signals of each of the pixels 100 arranged in the pixel array unit 20, and to measure the distance.

Furthermore, in the pixels 100, the electric charges generated by the photoelectric conversion units during an exposure period are transferred to and held in electric charge holding units after the elapse of the exposure period. The image signal is generated on the basis of the held electric charges. Each of the pixels 100 in the drawing includes two electric charge holding units, and can distribute and hold the electric charges generated by the photoelectric conversion units to and in the two charge holding units. Pulse train-shaped light is emitted from the light source 3 described in FIG. 1 to the object, and the electric charges generated by the photoelectric conversion of the reflected light from the object in the pixels 100 are distributed in synchronization with a pulse train of the emission light, whereby the reflected light can be modulated. A time shift from the emission light can be detected from an image signal of the modulated reflected light, and time of flight of the light from the emission of the light in the light source 3 to the detection of the reflected light from the object can be clocked. The distance to the object can be measured on the basis of this time of flight and the speed of light. Such ToF is referred to as indirect ToF (iToF).

Note that the vertical drive unit 30 is an example of an electric charge transfer control unit described in claims. The ranging unit 60 is an example of a processing circuit described in claims.

[Configuration of Pixel]

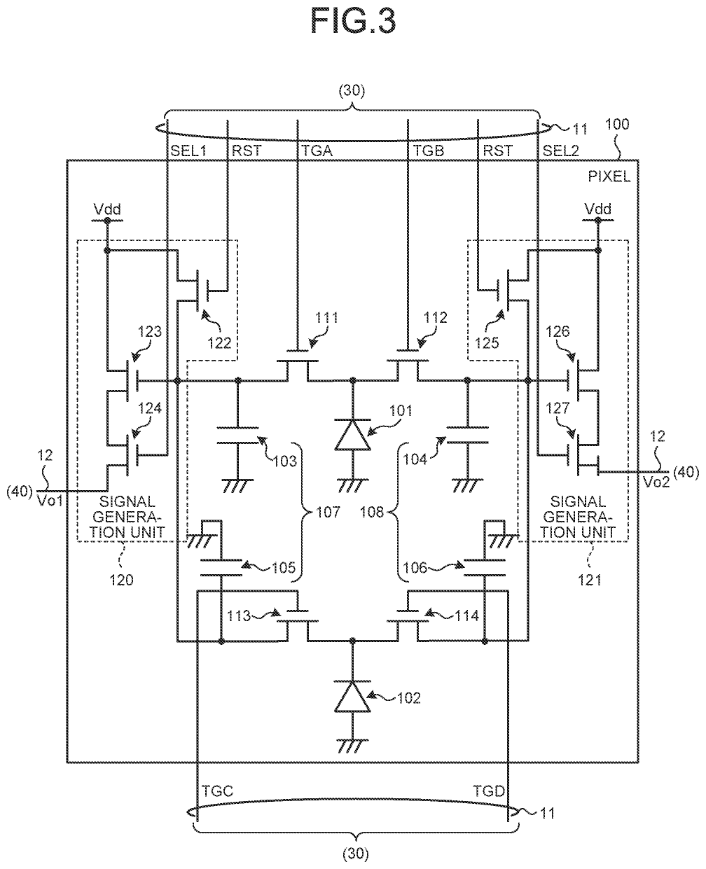

FIG. 3 is a view illustrating a configuration example of a pixel according to the first embodiment of the present disclosure. The drawing is a circuit diagram illustrating a configuration example of each of the pixels 100. The pixel 100 includes photoelectric conversion units 101 and 102, electric charge holding units 103 to 106, electric charge transfer units 111 to 114, and signal generation units 120 and 121. The electric charge transfer units 111 to 114 can include MOS transistors. The signal generation unit 120 can include MOS transistors 122 to 124, and the signal generation unit 121 can include MOS transistors 125 to 127. Furthermore, the electric charge transfer units 111 to 114 and the MOS transistors 122 to 127 can include n-channel MOS transistors.

Selection signal lines SEL1 and SEL2, a reset signal line RST, transfer signal lines TGA, TGB, TGC, and TGD, and output signal lines Vo1 and Vo2 are connected to the pixel 100. The signal line 11 includes selection signal lines SEL1 and SEL2, the reset signal line RST, and the transfer signal lines TGA, TGB, TGC, and TGD, and the signal line 12 includes output signal lines Vo1 and Vo2. Note that Vdd in the drawing is a power line that supplies power to the pixel 100.

An anode of the photoelectric conversion unit 101 is grounded, and a cathode is connected to a source of the electric charge transfer unit 111 and a source of the charge transfer unit 112. A gate of the electric charge transfer unit 111 is connected to the transfer signal line TGA. A drain of the electric charge transfer unit 111 is connected to a source of the MOS transistor 122, a gate of the MOS transistor 123, a drain of the electric charge transfer unit 113, and one ends of the electric charge holding units 103 and 105 connected in parallel. The other ends of the electric charge holding units 103 and 105 are grounded. A gate of the MOS transistor 122 is connected to the reset signal line RST, and a drain thereof is connected to the power line Vdd. A drain of the MOS transistor 123 is connected to the power line Vdd, and a source thereof is connected to a drain of the MOS transistor 124. A gate of the MOS transistor 124 is connected to the selection signal line SEL1, and a source thereof is connected to the output signal line Vo1.

A gate of the electric charge transfer unit 112 is connected to the transfer signal line TGB. A drain of the electric charge transfer unit 112 is connected to a source of the MOS transistor 125, a gate of the MOS transistor 126, a drain of the electric charge transfer unit 114, and one ends of the electric charge holding units 104 and 106 connected in parallel. The other ends of the electric charge holding units 104 and 106 are grounded. A gate of the MOS transistor 125 is connected to the reset signal line RST, and a drain thereof is connected to the power line Vdd. A drain of the MOS transistor 126 is connected to the power line Vdd, and a source thereof is connected to a drain of the MOS transistor 127. A gate of the MOS transistor 127 is connected to the selection signal line SEL2, and a source thereof is connected to the output signal line Vo2. A gate of the electric charge transfer unit 113 and a gate of the electric charge transfer unit 114 are respectively connected to the transfer signal line TGC and the transfer signal line TGD. A source of the electric charge transfer unit 113 and a source of the electric charge transfer unit 114 are commonly connected to a cathode of the photoelectric conversion unit 102. An anode of the photoelectric conversion unit 102 is grounded.

The photoelectric conversion units 101 and 102 perform photoelectric conversion of the incident light. As described above, photodiodes can be used for the photoelectric conversion units 101 and 102. Note that the photoelectric conversion unit 101 is an example of a first photoelectric conversion unit described in claims. The photoelectric conversion unit 102 is an example of a second photoelectric conversion unit described in claims.

The electric charge holding units 103 to 106 are capacitors that hold the electric charges generated by the photoelectric conversion units 101 and 102. As described later, the electric charge holding units 103 to 106 can include floating diffusion regions (FD) formed in a semiconductor substrate. As illustrated in the drawing, the electric charge holding units 103 and 105, and the electric charge holding units 104 and 106 are respectively connected in parallel.

The electric charge transfer units 111 to 114 transfer the electric charges generated by the photoelectric conversion unit 101 and the like to the electric charge holding unit 103 and the like. The electric charge transfer unit 111 transfers the electric charges generated by the photoelectric conversion unit 101 to the electric charge holding units 103 and 105. The electric charge transfer unit 112 transfers the electric charges generated by the photoelectric conversion unit 101 to the electric charge holding units 104 and 106. The electric charge transfer unit 113 transfers the electric charges generated by the photoelectric conversion unit 102 to the electric charge holding units 103 and 105. The electric charge transfer unit 114 transfers the electric charges generated by the photoelectric conversion unit 102 to the electric charge holding units 104 and 106. By making the electric charge transfer units 111 to 114 conductive, it is possible to transfer the electric charges of the photoelectric conversion unit 101 and the like to the electric charge holding unit 103 and the like. The transfers of the electric charges in the electric charge transfer units 111 to 114 are respectively controlled by control signals from the transfer signal lines TGA, TGB, TGC, and TGD.

Note that the electric charge transfer unit 111 is an example of a first electric charge transfer unit described in claims. The electric charge transfer unit 112 is an example of a second electric charge transfer unit described in claims. The electric charge transfer unit 113 is an example of a third electric charge transfer unit described in claims. The electric charge transfer unit 114 is an example of a fourth electric charge transfer unit described in claims.

Here, the electric charge holding unit to which the electric charges are commonly transferred by the electric charge transfer units 111 and 113 is referred to as a first electric charge holding unit, and the electric charge holding unit to which the electric charges are commonly transferred by the electric charge transfer units 112 and 114 is referred to as a second electric charge holding unit. In the drawing, the electric charge holding units 103 and 105 connected in parallel correspond to the first electric charge holding unit (first electric charge holding unit 107), and the electric charge holding units 104 and 106 connected in parallel correspond to the second electric charge holding unit (second electric charge holding unit 108). Note that the configuration of the pixel 100 is not limited to this example. For example, any of the electric charge holding units 103 and 105 can be omitted, and any of the electric charge holding units 104 and 106 can be omitted.

The signal generation units 120 and 121 are circuits that generate the image signals on the basis of the electric charges held in the first electric charge holding unit 107 and the second electric charge holding unit 108. The signal generation unit 120 generates a first image signal on the basis of the electric charges held in the first electric charge holding unit 107, and the signal generation unit 121 generates a second image signal on the basis of the electric charges held in the second electric charge holding unit 108. In such a manner, the signal generation units 120 and 121 generate two image signals.

The MOS transistors 122 and 125 are transistors that discharge the electric charges held in the first electric charge holding unit 107 and the like to the power line Vdd, and perform resetting. The MOS transistor 122 resets the first electric charge holding unit 107, and the MOS transistor 125 resets the second electric charge holding unit 108. At the time of this resetting, it is possible to further perform resetting of the photoelectric conversion unit 101 and the like by making the electric charge transfer unit 111 and the like conductive. The resetting by the MOS transistors 122 and 125 is controlled by a control signal from the reset signal line RST.

The MOS transistors 123 and 126 are transistors that generate image signals corresponding to the electric charges held in the electric charge holding unit 103 and the like. The MOS transistors 123 and 126 are included in a source follower circuit together with a constant current circuit 41 of the column signal processing unit 40 (described later). A signal of a voltage corresponding to a potential of the electric charge holding unit 103 and the like connected to the gate is output to a source terminal. This signal becomes the image signal. The MOS transistor 123 generates the image signal according to the electric charges held in the first electric charge holding unit 107, and the MOS transistor 126 generates the image signal according to the electric charges held in the second electric charge holding unit 108.

The MOS transistors 124 and 127 are transistors that respectively output the image signals respectively generated by the MOS transistors 123 and 126 to the output signal lines Vo1 and Vo2. The MOS transistor 124 is controlled by the control signal from the selection signal line SEL1 and outputs the image signal generated by the MOS transistor 123 to the output signal line Vo1. The MOS transistor 127 is controlled by the control signal from the selection signal line SEL2, and outputs the image signal generated by the MOS transistor 126 to the output signal line Vo2.

A procedure of image signal generation will be described with the signal generation unit 120 as an example. First, the MOS transistor 122 and the electric charge transfer unit 111 are made conductive and the first electric charge holding unit 107 and the photoelectric conversion unit 101 are reset. After the elapse of a predetermined exposure period, the MOS transistor 122 is made conductive again and the first electric charge holding unit 107 is reset. Then, the electric charge transfer unit 111 is made conductive and the electric charges of the photoelectric conversion unit 101 are transferred to the first electric charge holding unit 107. As a result, the MOS transistor 123 generates the image signal corresponding to the electric charges held in the first electric charge holding unit 107. The MOS transistor 124 is made conductive at output timing of the image signal in the pixel 100, whereby the generated image signal is output to the output signal line Vo1. Note that since CDS (described later) is performed, the signal generation unit 120 can also generate and output the image signal (image signal at the time of resetting) at the time of resetting after the elapse of the exposure period described above.

In generating the image data described above, after the elapse of the exposure period, one of the electric charge transfer units 111 and 113 or the electric charge transfer units 112 and 114 is made conductive, and the electric charges are transferred to corresponding one of the first electric charge holding unit 107 or the second electric charge holding unit 108. Then, the image signal is generated by any of the signal generation unit 120 or 121 connected to the electric charge holding unit to which the electric charges are transferred. The generated image signal is processed by the image processing unit 50 in FIG. 2 and output as image data.

When a phase difference of the object is detected, the photoelectric conversion units 101 and 102 are used as a pair of pupil-divided photoelectric conversion units. Specifically, it is possible to perform control to individually transfer the electric charges respectively generated by the photoelectric conversion units 101 and 102 at the same time and cause the first electric charge holding unit 107 and the second electric charge holding unit 108 to exclusively hold the electric charges. Hereinafter, such an electric charge transfer control method is referred to as individual transfer control. The two image signals are generated on the basis of the electric charges transferred and held by the individual transfer control. That is, the two image signals corresponding to the electric charges of the photoelectric conversion units 101 and 102 are generated. The generated image signals correspond to the above-described phase difference signals. The image signals corresponding to the phase difference signals are used to detect the phase difference of the incident light in the ranging unit 60 of FIG. 2. Then, a focus of the object is detected by the ranging unit 60, and the distance to the object is measured.

In the individual transfer control described above, it is possible to perform control to make any of the electric charge transfer units 111 and 114 or the electric charge transfer units 112 and 113 conductive at the same time. As a result, the electric charges respectively generated by the photoelectric conversion units 101 and 102 are individually transferred to the first electric charge holding unit 107 and the second electric charge holding unit 108, and are exclusively held.

Furthermore, in the individual transfer control described above, it is possible to perform control to make any two charge transfer units of the electric charge transfer units 111 and 113 or the electric charge transfer units 112 and 114 conductive in different periods. For example, in a case where two electric charge transfer units of the electric charge transfer unit 111 and the electric charge transfer unit 113 are selected, the electric charge transfer unit 111 is made conductive to transfer the electric charges of the photoelectric conversion unit 101 to the first electric charge holding unit 107, and the image signal (phase difference signal) is generated by the signal generation unit 120. Then, after the first electric charge holding unit 107 is reset, the electric charge transfer unit 113 is made conductive, the electric charges of the photoelectric conversion unit 102 are transferred to the first electric charge holding unit 107, and the phase difference signal is generated. In this case, the electric charges respectively generated by the photoelectric conversion units 101 and 102 are individually transferred to any of the first electric charge holding unit 107 or the second electric charge holding unit 108, and are exclusively held.

In a case where the ToF method is applied, it is possible to perform control in which the electric charges respectively generated by the photoelectric conversion units 101 and 102 at the same time are commonly transferred to and simultaneously and collectively held in any of the first electric charge holding unit 107 or the second electric charge holding unit 108. Hereinafter, such an electric charge transfer control method is referred to as common transfer control. When this common transfer control is performed, the first electric charge holding unit 107 and the second electric charge holding unit 108 are alternately selected and the electric charges are transferred, whereby the electric charges generated by the photoelectric conversion units 101 and 102 can be distributed. This electric charge distribution is performed a plurality of times, and the electric charges generated by the photoelectric conversion are accumulated in the first electric charge holding unit 107 and the second electric charge holding unit 108. Then, the image signals corresponding to the distributed electric charges can be respectively generated by the signal generation units 120 and 121, and the reflected light from the object can be modulated.

In the common transfer control described above, it is possible to perform control to make any of the electric charge transfer units 111 and 113 or the electric charge transfer units 112 and 114 conductive at the same time. As a result, the electric charges generated by the photoelectric conversion units 101 and 102 are commonly transferred to any of the first electric charge holding unit 107 or the second electric charge holding unit 108, and are collectively held at the same time.

The ranging unit 60 in FIG. 2 can measure the distance to the object by the ToF method on the basis of the image signals generated by the common transfer control in addition to the measurement of the distance to the object based on the phase difference signals.

[Configuration of Column Signal Processing Unit]

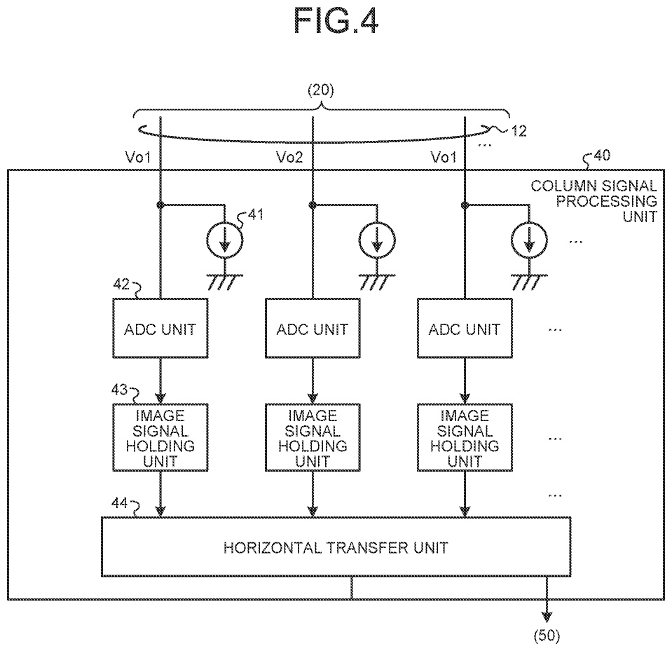

FIG. 4 is a view illustrating a configuration example of a column signal processing unit according to the embodiment of the present disclosure. The drawing is a view illustrating a configuration example of the column signal processing unit 40. The column signal processing unit 40 includes the constant current circuit 41, an analog-digital conversion (ADC) unit 42, an image signal holding unit 43, and a horizontal transfer unit 44. Among these, the constant current circuit 41, the analog-digital conversion unit 42, and the image signal holding unit 43 are arranged for each of the plurality of signal lines 12.

The constant current circuit 41 is a circuit included in a load of the MOS transistor 123 and the MOS transistor 126 described in FIG. 3. A sink-side terminal of the constant current circuit 41 is connected to the signal line 12 (output signal line Vo1 or Vo2 in FIG. 3), and a source side terminal thereof is grounded. As a result, the constant current circuit 41 is included in the source follower circuit together with the MOS transistors 123 and 126. Each of the image signals is transmitted as a signal of a voltage corresponding to the incident light to the signal line 11 to which the sink-side terminal of the constant current circuit 41 is connected.

The analog-digital conversion unit 42 performs analog-digital conversion of the image signals. This analog-digital conversion unit 42 converts analog image signals generated by the pixels 100 into digital image signals. The digital image signals after the conversion are output to the image signal holding unit 43.

The image signal holding unit 43 holds the image signals converted into the digital signals by the analog-digital conversion unit 42. In addition, the image signal holding unit 43 can perform correlated double sampling (CDS). This CDS is processing of removing an offset (noise) by obtaining a difference of the image signal at the time of the resetting described above from the image signal generated by the exposure. Electric charges that are not discharged by the resetting remain in the electric charge holding unit 103 and the like described in FIG. 3. A signal component based on the remaining electric charges becomes an offset component of the image signals and causes noise. Thus, it is possible to remove the offset component by holding the image signal at the time of the resetting and subtracting the image signal at the time of the resetting (reset level) from the image signal based on the electric charges generated and transferred at the time of the exposure (signal level). The image signal holding unit 43 in the drawing can hold the image signal at the time of the resetting and perform processing of subtracting the reset level from the signal level. By performing this CDS, the noise of the image signals can be reduced.

The horizontal transfer unit 44 transfers the image signals. Outputs of all the image signal holding units 43 respectively arranged for the signal lines 12 are connected to the horizontal transfer unit 44 in the drawing. The horizontal transfer unit 44 sequentially transfers and outputs the image signals output from the image signal holding units 43. For example, the horizontal transfer unit 44 can perform the transfer in order from an image signal of the image signal holding unit 43 at the right end among the plurality of image signal holding units 43 arranged in the column signal processing unit 40 in the drawing and perform an output thereof to the image processing unit 50.

[Configuration of Plane of Pixel]

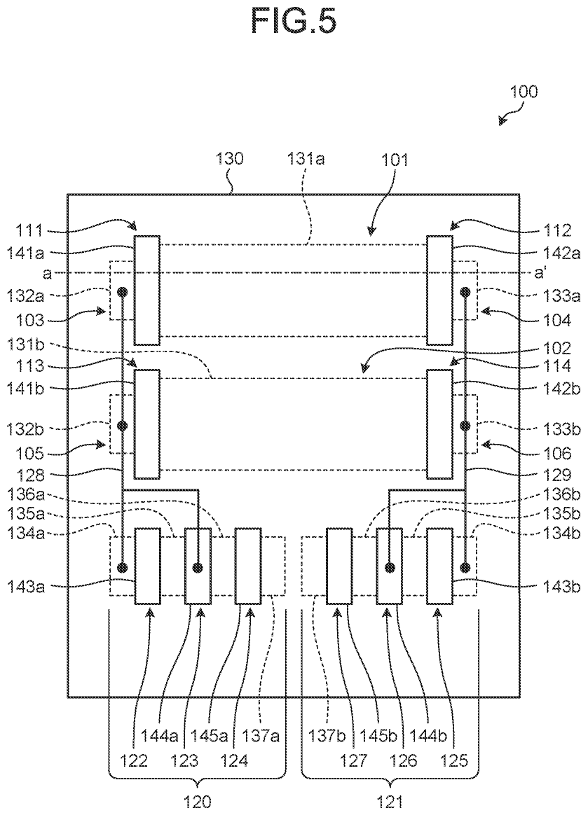

FIG. 5 is a plan view illustrating a configuration example of the pixel according to the first embodiment of the present disclosure. The drawing is a plan view illustrating a configuration example of each of the pixels 100. The pixel 100 in the drawing is formed on a semiconductor substrate 130. In the drawing, a dotted rectangle represents a semiconductor region formed on the semiconductor substrate 130. A solid rectangle represents a gate of a MOS transistor arranged adjacently on a front surface side of the semiconductor substrate 130.

A semiconductor region 131a included in the photoelectric conversion unit 101 and a semiconductor region 131b included in the photoelectric conversion unit 102 are arranged side by side in an upper half region of the pixel 100 in the drawing. A gate 141a of the electric charge transfer unit 111 and a semiconductor region 132a are arranged in a manner of being adjacent to a left side of the photoelectric conversion unit 101. The electric charge transfer unit 111 is a MOS transistor having the semiconductor regions 131a and 132a respectively as a source region and a drain region. In addition, the semiconductor region 132a is included in the electric charge holding unit 103. A gate 142a of the electric charge transfer unit 112 and a semiconductor region 133a are arranged in a manner of being adjacent to a right side of the photoelectric conversion unit 101. The electric charge transfer unit 112 is a MOS transistor having the semiconductor region 131a and the semiconductor region 133a respectively as a source region and a drain region. In addition, the semiconductor region 133a is included in the electric charge holding unit 104.

Furthermore, a gate 141b of the electric charge transfer unit 113 and a semiconductor region 132b are arranged in a manner of being adjacent to a left side of the photoelectric conversion unit 102. The electric charge transfer unit 113 is a MOS transistor having the semiconductor regions 131b and 132b respectively as a source region and a drain region. In addition, the semiconductor region 132b is included in the electric charge holding unit 105. A gate 142b of the electric charge transfer unit 114 and a semiconductor region 133b are arranged in a manner of being adjacent to a right side of the photoelectric conversion unit 101. The electric charge transfer unit 114 is a MOS transistor having the semiconductor regions 131b and 133b respectively as a source region and a drain region. In addition, the semiconductor region 133b is included in the electric charge holding unit 106.

The signal generation unit 120 is arranged at the lower left of the pixel 100 in the drawing. In this signal generation unit 120, a semiconductor region 134a, a gate 143a, a semiconductor region 135a, a gate 144a, a semiconductor region 136a, a gate 145a, and a semiconductor region 137a are arranged in this order from a left end. The semiconductor region 134a and the gate 143a are included in a source region and a gate of the MOS transistor 122. The semiconductor region 135a is included in a drain region of the MOS transistor 122, and is also included in a drain region of the MOS transistor 123. The gate 144a is included in a gate of the MOS transistor 123. The semiconductor region 136a is included in a source region of the MOS transistor 123, and is also included in a drain region of the MOS transistor 124. The gate 145a and the semiconductor region 137a are respectively included in a gate and a source region of the MOS transistor 124. The semiconductor region 132a, the semiconductor region 132b, the semiconductor region 134a, and the gate 144a are connected by a wiring line 128 in the drawing. A black circle of the wiring line 128 represents a contact plug that connects the wiring line and the semiconductor region. Description of other wiring lines is omitted.

The signal generation unit 121 is arranged at the lower right of the pixel 100 in the drawing. The signal generation unit 121 in the drawing can have a configuration in which the signal generation unit 120 is arranged symmetrically. Specifically, in the signal generation unit 121, a semiconductor region 134b, a gate 143b, a semiconductor region 135b, a gate 144b, a semiconductor region 136b, a gate 145b, and a semiconductor region 137b are arranged in this order from a right end, and the MOS transistors 125, 126, and 127 are arranged in this order from the right end. The semiconductor region 133a, the semiconductor region 133b, the semiconductor region 134b and the gate 144b are connected by a wiring line 129 in the drawing.

[Configuration of Cross-Section of Pixel]

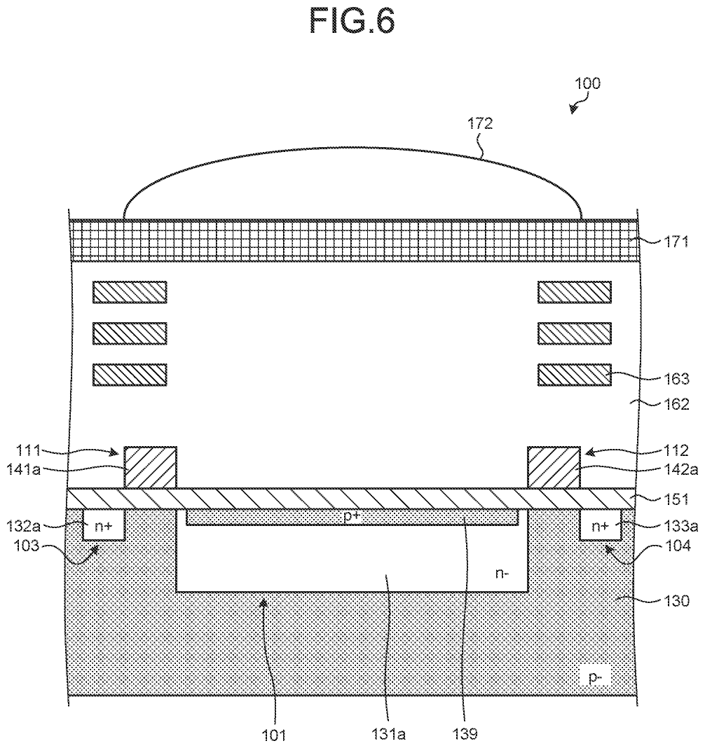

FIG. 6 is a cross-sectional view illustrating a configuration example of the pixel according to the first embodiment of the present disclosure. The drawing is a cross-sectional view illustrating a configuration example of each of the pixels 100, and is a cross-sectional view taken along a line a-a′ in FIG. 5. The pixel 100 in the drawing includes the semiconductor substrate 130, a wiring region including an insulating layer 162 and a wiring layer 163, a protective film 171, and an on-chip lens 172.

The semiconductor substrate 130 is a semiconductor substrate on which a diffusion region of an element of the pixel 100, or the like is formed. This semiconductor substrate 130 can include, for example, silicon (Si). The diffusion region of the element can be arranged in a well region formed in the semiconductor substrate 130. For convenience, the semiconductor substrate 130 in the drawing is assumed to be configured in a p-type well region. By arrangement of an n-type semiconductor region in the p-type well region, the diffusion region of the element can be formed. In the drawing, the photoelectric conversion unit 101, the electric charge holding units 103 and 104, and the electric charge transfer units 111 and 112 are illustrated.

The photoelectric conversion unit 101 includes an n-type semiconductor region 131a. Specifically, a photodiode including a p-n junction between the n-type semiconductor region 131a and the surrounding p-type well region corresponds to the photoelectric conversion unit 101. Electric charges generated by the photoelectric conversion of the incident light are accumulated in the n-type semiconductor region 131a.

Note that a semiconductor region 139 can be arranged between the n-type semiconductor region 131a and a front surface-side surface of the semiconductor substrate 130. This semiconductor region 139 is configured to have p-type relatively high impurity concentration, and pinning of a surface level of the semiconductor substrate 130 is performed. By arranging this semiconductor region 139, it is possible to reduce a dark current that is a current generated by movement of the electric charges with respect to the surface level, and it is possible to reduce noise of an image signal which noise is caused by the dark current.

The electric charge holding units 103 and 104 include n-type semiconductor regions 132a and 133a having relatively high impurity concentration. The electric charge holding unit including the semiconductor region is referred to as a floating diffusion region (FD).

The electric charge transfer unit 111 includes the semiconductor regions 131a and 132a as described above, and a channel is formed in a well region between the semiconductor regions 131a and 132a. The gate 141a is arranged in a manner of being adjacent to this well region. Furthermore, the electric charge transfer unit 112 includes the semiconductor regions 131a and 133a, and a channel is formed in a well region between the semiconductor regions 131a and 133a. The gate 142a is arranged in a manner of being adjacent to this well region. When these electric charge transfer units 111 and 112 are brought into the conductive state, the electric charges accumulated in the n-type semiconductor region 131a of the photoelectric conversion unit 101 are transferred to and held in the n-type semiconductor region 132a of the electric charge holding unit 103 and the n-type semiconductor region 133a of the electric charge holding unit 104, respectively. Note that the gates 141a and 142a can include, for example, polycrystalline silicon.

Note that an insulating film 151 is arranged on a front surface side of the semiconductor substrate 130. This insulating film 151 can include, for example, a silicon oxide (SiO₂). The insulating film 151 between the semiconductor substrate 130 and the gate 141a are included in a gate insulating film.

The wiring layer 163 is a wiring line that transfers a signal to an element or the like of the pixel 100. This wiring layer 163 can include metal such as copper (Cu) or aluminum (Al). The insulating layer 162 insulates the wiring layer 163. This insulating layer 162 can include, for example, SiO₂. In addition, the wiring layer 163 and the insulating layer 162 can be configured in multiple layers. As described above, the insulating layer 162 and the wiring layer 163 are included in the wiring region.

The protective film 171 is arranged in a manner of being adjacent to the insulating layer 162 in the wiring region and protects the wiring region. This protective film 171 can include, for example, an insulator such as SiO₂.

The on-chip lens 172 is a lens that is formed in a hemispherical shape and that collects the incident light on the photoelectric conversion unit 101 and the like. This on-chip lens 172 is arranged for each of the pixels 100 and collects the incident light. The on-chip lens 172 can include an inorganic material such as a silicon nitride (SiN) or an organic material such as an acrylic resin.

Note that the pixel 100 in the drawing corresponds to a front-illuminated imaging element in which the incident light is emitted to the front surface side of the semiconductor substrate 130.

[Generation of Image Signal]

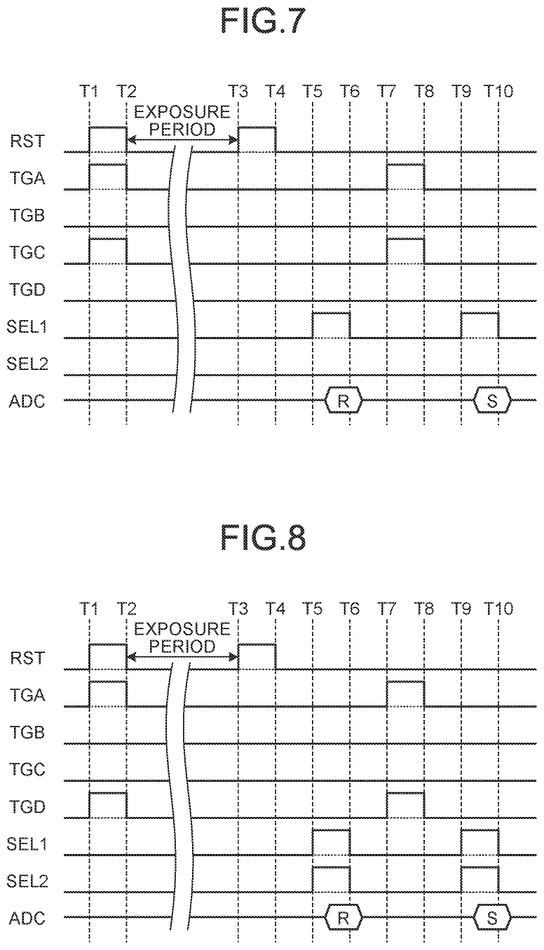

FIG. 7 is a view illustrating an example of generation of an image signal according to the embodiment of the present disclosure. The drawing is a timing chart illustrating an example of generation of an image signal in the pixel 100 described in FIG. 3. In the drawing, RST, TGA, TGB, TGC, and TGD represent binarized signal waveforms of the reset signal line RST, the transfer signal line TGA, the transfer signal line TGB, the transfer signal line TGC, and the transfer signal line TGD, respectively. Similarly, SEL1 and SEL2 represent binarized signal waveforms of the selection signal line SEL1 and the selection signal line SEL2, respectively.

As described above, each of the reset signal line RST, the transfer signal line TGA, the transfer signal line TGB, the transfer signal line TGC, the transfer signal line TGD, the selection signal line SEL1, and the selection signal line SEL2 is connected to the gate of the MOS transistor. By applying a voltage exceeding a threshold of a gate-source voltage Vgs of the MOS transistor to the gate, it is possible to bring the MOS transistor into the conductive state. Hereinafter, a signal having a voltage exceeding the threshold of Vgs is referred to as an ON signal. A portion having a value “1” of a signal waveform such as RST in the drawing represents the ON signal. Note that a broken line in the drawing represents a signal level of 0V (value “0”). Furthermore, ADC in the drawing represents an output of the analog-digital conversion unit 42 described in FIG. 4.

First, in a period from T1 to T2, the ON signal is output to the reset signal line RST and the MOS transistors 122 and 125 are made conductive. At the same time, the ON signal is output to the transfer signal lines TGA and TGC and the electric charge transfer units 111 and 113 are made conductive. As a result, the photoelectric conversion units 101 and 102 and the first electric charge holding unit 107 (electric charge holding units 103 and 105) are reset. The exposure period is started by this resetting.

After the elapse of the predetermined exposure period, the ON signal is output to the reset signal line RST in T3 to T4, and the first electric charge holding unit 107 is reset again.

Then, in a period from T5 to T6, the ON signal is output to the selection signal line SEL1, and an image signal generated by the signal generation unit 120 is output to the output signal line Vo1. This output image signal is converted into a digital image signal by the analog-digital conversion unit 42 and is output to the image signal holding unit 43. This output image signal corresponds to the image signal at the time of the resetting. In the drawing, this image signal is expressed as “R”.

Then, in a period from T7 to T8, the ON signal is output to the transfer signal lines TGA and TGC and makes the electric charge transfer units 111 and 113 conductive, and the electric charges generated by the photoelectric conversion units 101 and 102 are transferred to and held in the first electric charge holding unit 107.

Then, in a period from T9 to T10, the ON signal is output to the selection signal line SEL1, and an image signal generated by the signal generation unit 120 is output to the output signal line Vo1. This output image signal is converted into a digital image signal and is output to the image signal holding unit 43. This image signal is expressed as “S”. Then, the image signal holding unit 43 subtracts the image signal R from the image signal S and performs CDS.

The image signal is generated by the above processing. The common transfer control of causing any of the first electric charge holding unit 107 or the second electric charge holding unit 108 to simultaneously and collectively hold the electric charges simultaneously generated by the photoelectric conversion units 101 and 102 is performed in the period of T7 to T8. Note that in the above-described processing, the electric charges generated by the photoelectric conversion units 101 and 102 can also be transferred to the second electric charge holding unit 108 (charge holding units 104 and 106) by utilization of the electric charge transfer units 112 and 114. At this time, the image signal R and the image signal S are generated by the signal generation unit 121.

In such a manner, by outputting the control signal (ON signal) corresponding to the common transfer control in the vertical drive unit 30, it is possible to perform the common transfer control and to generate the image signal of the subject or the object.

[First Generation of Image Signal for Phase Difference Detection]

FIG. 8 is a view illustrating an example of generation of an image signal in ranging according to the embodiment of the present disclosure. The drawing is a timing chart illustrating an example of generation of an image signal in the pixel 100 similarly to FIG. 7. There is a difference from the generation of the image signal in FIG. 7 in a point that an image signal of when a phase difference of incident light from the object is detected and ranging is performed is generated.

First, in a period from T1 to T2, the ON signal is output to the reset signal line RST and the ON signal is also output to the transfer signal lines TGA and TGD, whereby the MOS transistors 122 and 125 and the electric charge transfer units 111 and 114 are made conductive. As a result, the photoelectric conversion units 101 and 102 and the first electric charge holding unit 107 and the second electric charge holding units 108 are reset. The exposure period is started by this resetting.

After the elapse of predetermined exposure period, the ON signal is output to the reset signal line RST in T3 to T4, and the first electric charge holding unit 107 and the second electric charge holding unit 108 are reset again.

Then, in a period from T5 to T6, the ON signal is output to the selection signal lines SEL1 and SEL2, and image signals R at the time of the resetting which signals are generated by the signal generation units 120 and 121 are respectively output to the output signal lines Vo1 and Vo2.

Then, in a period from T7 to T8, the ON signal is output to the transfer signal lines TGA and TGC and the electric charge transfer units 111 and 114 are made conductive, whereby the electric charges generated by the photoelectric conversion units 101 and 102 are individually transferred to and held in the first electric charge holding unit 107 and the second electric charge holding unit 108.

Then, in a period from T9 to T10, the ON signal is output to the selection signal lines SEL1 and SEL2, and image signals S generated by the signal generation units 120 and 121 are respectively output to the output signal lines Vo1 and Vo2. The output image signals R and image signals S are converted into digital image signals, and CDS is performed.

As described above, in the period from T7 to T8, the individual transfer control in which the electric charges respectively generated by the photoelectric conversion units 101 and 102 at the same time are individually transferred to and exclusively held in the first electric charge holding unit 107 and the second electric charge holding unit 108 is performed. Phase difference signals that are image signals generated on the basis of the pair of pupil-divided photoelectric conversion units 101 and 102 are output to the output signal lines Vo1 and Vo2. Note that in the above-described processing, the electric charges generated by the photoelectric conversion units 101 and 102 can also be respectively transferred to the second electric charge holding unit 108 and the first electric charge holding units 107 by utilization of the electric charge transfer units 112 and 113.

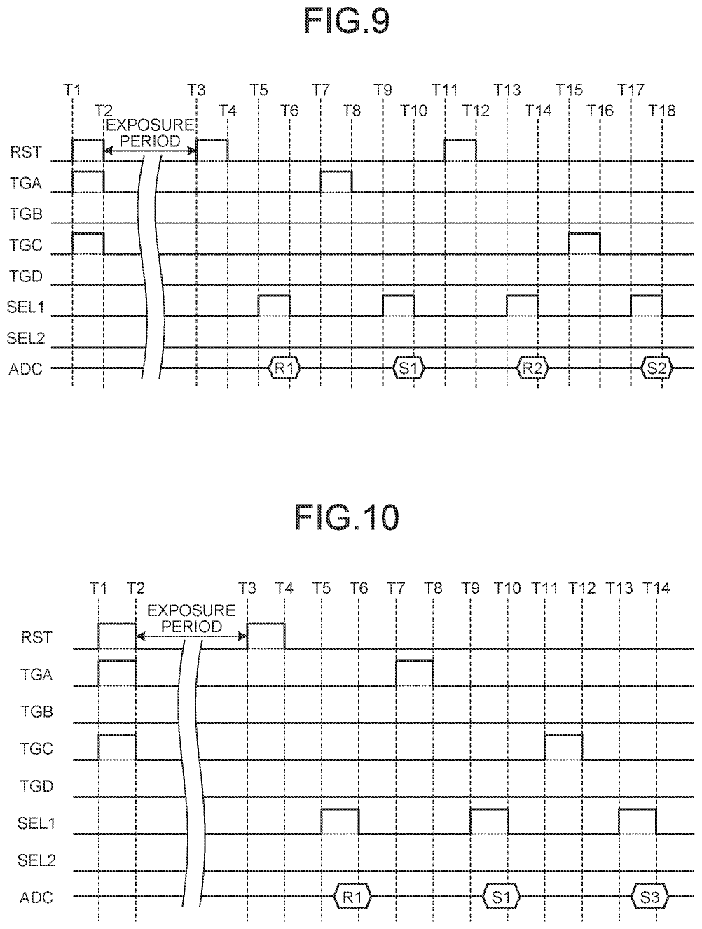

In such a manner, by outputting the control signal (ON signal) corresponding to the individual transfer control in the vertical drive unit 30, it is possible to perform the individual transfer control and to simultaneously generate a pair of phase difference signals. Time required for generation of the phase difference signals can be shortened as compared with the processing described later in FIG. 9.

[Second Generation of Image Signal for Phase Difference Detection]

FIG. 9 is a view illustrating another example of generation of an image signal in ranging according to the embodiment of the present disclosure. Similarly to FIG. 8, the drawing is a timing chart illustrating an example of generation of an image signal of when a phase difference in the pixel 100 is detected and ranging is performed. There is a difference from the generation of the image signal in FIG. 8 in a point that the electric charges generated by the photoelectric conversion units 101 and 102 are transferred to the same electric charge holding unit.

First, in a period from T1 to T2, the ON signal is output to the reset signal line RST and the ON signal is also output to the transfer signal lines TGA and TGC, whereby the MOS transistors 122 and 125 and the electric charge transfer units 111 and 113 are made conductive. As a result, the photoelectric conversion units 101 and 102 and the first electric charge holding unit 107 are reset. The exposure period is started by this resetting.

After the elapse of the predetermined exposure period, the ON signal is output to the reset signal line RST in T3 to T4, and the first electric charge holding unit 107 is reset again.

Then, in a period from T5 to T6, the ON signal is output to the selection signal line SEL1, and an image signal R1 at the time of the resetting which signal is generated by the signal generation unit 120 is output to the output signal line Vo1.

Then, in a period from T7 to T8, the ON signal is output to the transfer signal line TGA and the electric charge transfer unit 1l1 is made conductive, whereby the electric charges generated by the photoelectric conversion unit 101 are transferred to and held in the first electric charge holding unit 107.

Then, in a period from T9 to T10, the ON signal is output to the selection signal line SEL1, and an image signal S1 generated by the signal generation unit 120 is output to the output signal line Vo1. The output image signal R1 and image signal S1 are converted into digital image signals, and CDS is performed.

Then, in T11 to T12, the ON signal is output to the reset signal line RST, and the first electric charge holding unit 107 is reset again.

Then, in a period from T13 to T14, the ON signal is output to the selection signal line SEL1, and an image signal R2 at the time of the resetting which signal is generated by the signal generation unit 120 is output to the output signal line Vo1.

Then, in a period from T15 to T16, the ON signal is output to the transfer signal line TGC and the electric charge transfer unit 113 is made conductive, whereby the electric charges generated by the photoelectric conversion unit 102 are transferred to and held in the first electric charge holding unit 107.

Then, in a period from T7 to T18, the ON signal is output to the selection signal line SEL1, and an image signal S2 generated by the signal generation unit 120 is output to the output signal line Vo1. The output image signal R2 and image signal S2 are converted into digital image signals, and CDS is performed.

As described above, the electric charges generated by the photoelectric conversion unit 101 is transferred to and held in the first electric charge holding unit 107 in the period from T7 to T8, and a phase difference signal based on the photoelectric conversion by the photoelectric conversion unit 101 is generated. Then, the electric charges generated by the photoelectric conversion unit 102 is transferred to and held in the first electric charge holding unit 107 in the period from T15 to T16, and a phase difference signal based on the photoelectric conversion by the photoelectric conversion unit 102 is generated. That is, the individual transfer control of causing the electric charges generated by the photoelectric conversion units 101 and 102 to be transferred to the first electric charge holding unit 107 in different periods and exclusively held is performed. The phase difference signals generated by the pair of pupil-divided photoelectric conversion units 101 and 102 are sequentially output to the output signal line Vo1. Note that in the above-described processing, the electric charges generated by the photoelectric conversion units 101 and 102 can also be transferred to the second electric charge holding unit 108 by utilization of the electric charge transfer units 112 and 114.

As described above, by outputting the control signal (ON signal) corresponding to the individual transfer control in the vertical drive unit 30, it is possible to perform the individual transfer control and to generate a pair of phase difference signals of the incident light of the object by using the same electric charge holding unit and signal generation unit. A mutual error between the pair of phase difference signals can be reduced as compared with the processing described in FIG. 8.

[Third Generation of Image Signal for Phase Difference Detection]

FIG. 10 is a view illustrating another example of generation of an image signal in ranging according to the embodiment of the present disclosure. Similarly to FIG. 9, the drawing is a timing chart illustrating an example of generation of an image signal of when a phase difference in the pixel 100 is detected and ranging is performed. There is a difference from the generation of the image signal in FIG. 9 in a point that the number of times of resetting of the electric charge holding unit is reduced.

Since processing in a period from T1 to T10 is similar to the processing in FIG. 9, the description thereof will be omitted. Note that CDS is performed on an image signal S1 output at T10, and a phase difference signal corresponding to the photoelectric conversion unit 101 is generated.

Then, in a period from T11 to T12, the ON signal is output to the transfer signal line TGC and the electric charge transfer unit 113 is made conductive, whereby the electric charges generated by the photoelectric conversion unit 102 are transferred to and held in the first electric charge holding unit 107. The first electric charge holding unit 107 holds the electric charges of the photoelectric conversion unit 102 in addition to the electric charges, which are transferred in the period of T7 to T8, of the photoelectric conversion unit 101.

Then, in a period from T13 to T14, the ON signal is output to the selection signal line SEL1, and an image signal S3 generated by the signal generation unit 120 is output to the output signal line Vo1. The image signal S3 is held in the image signal holding unit 43, and the image signal S1 after CDS is subtracted therefrom. As a result, a phase difference signal corresponding to the photoelectric conversion unit 102 is generated.

As described above, the pair of phase difference signals can be generated by resetting of the first electric charge holding unit 107 once, and time required for generation of the phase difference signals can be shortened. As compared with the processing described in FIG. 9, the phase difference signals can be generated at high speed.

[Generation of Image Signal for ToF Method]

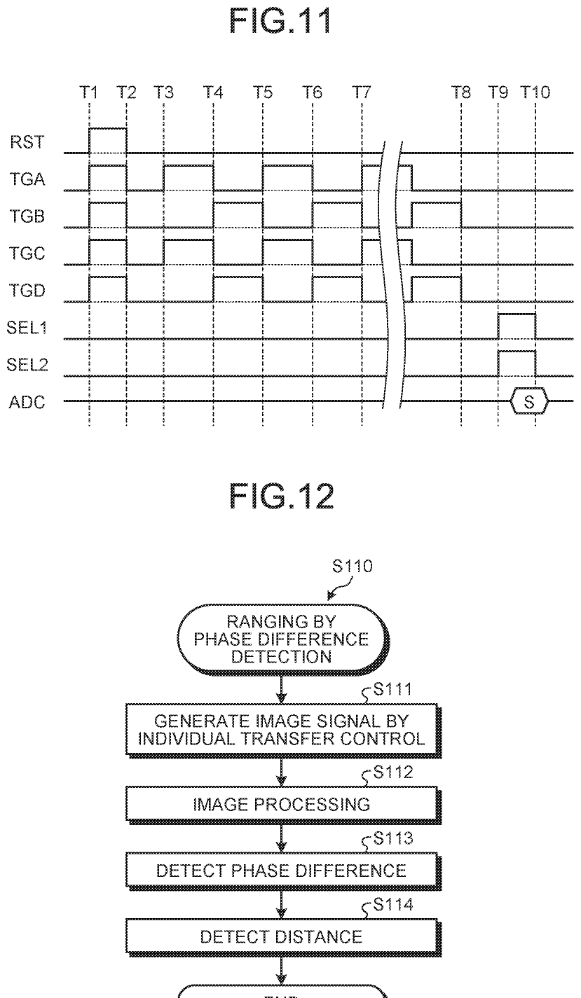

FIG. 11 is a view illustrating another example of generation of an image signal in ranging according to the embodiment of the present disclosure. Similarly to FIG. 8, the drawing is a timing chart illustrating an example of generation of an image signal in the pixel 100 of when ranging is performed. There is a difference from the generation of the image signal in FIG. 8 in a point that the electric charges generated by the photoelectric conversion units 101 and 102 are distributed in order to perform ranging by the ToF method.

First, in a period from T1 to T2, the ON signal is output to the reset signal line RST and the ON signal is also output to the transfer signal lines TGA, TGB, TGC, and TGD, whereby the MOS transistors 122 and 125 and the electric charge transfer units 111 and 114 are made conductive. As a result, the photoelectric conversion units 101 and 102 and the first electric charge holding unit 107 and the second electric charge holding units 108 are reset.

Then, in a period from T3 to T4, the ON signal is output to the transfer signal lines TGA and TGC and the electric charge transfer units 111 and 113 are made conductive, whereby the electric charges generated by the photoelectric conversion units 101 and 102 are transferred to and held in the first electric charge holding unit 107.

Then, in a period from T4 to T5, the ON signal is output to the transfer signal lines TGB and TGD and the electric charge transfer units 112 and 114 are made conductive, whereby the electric charges generated by the photoelectric conversion units 101 and 102 are transferred to and held in the second electric charge holding unit 108.

Then, in a period from T5 to T6, the ON signal is output to the transfer signal lines TGA and TGC and the electric charge transfer units 111 and 113 are made conductive. Electric charges newly generated in the photoelectric conversion units 101 and 102 are transferred to the first electric charge holding unit 107, and are integrated with the electric charges transferred in the period of T3 to T4.

Then, in a period from T6 to T7, the ON signal is output to the transfer signal lines TGB and TGD and the electric charge transfer units 112 and 114 are made conductive. Electric charges newly generated in the photoelectric conversion units 101 and 102 are transferred to the second electric charge holding unit 108, and are integrated with the electric charges transferred in the period of T4 to T5.

Then, the processing of T5 to T7 is repeated a predetermined number of times, and electric charges are accumulated in the first electric charge holding unit 107 and the second electric charge holding unit 108.

In a period from T9 to T10, the ON signal is output to the selection signal lines SEL1 and SEL2, and image signals S generated by the signal generation units 120 and 121 are respectively output to the output signal lines Vo1 and Vo2.

From the above processing, in each period in and after T3, the common transfer control of causing any of the first electric charge holding unit 107 or the second electric charge holding unit 108 to simultaneously and collectively hold the electric charges generated by the photoelectric conversion units 101 and 102 is performed. In addition, distribution in which the electric charges generated by the photoelectric conversion units 101 and 102 are alternately transferred to and held in the first electric charge holding unit 107 and the second electric charge holding unit 108 is performed. By generating a pair of image signals based on the distributed electric charges, the reflected light from the object can be modulated.

The electric charges are distributed in two phases of 0 degrees and 90 degrees in the same cycle as the pulse train-shaped emission light from the light source 3 described in FIG. 1. That is, two modulation signals that are an image signal generated by distribution in the same phase as the emission light and an image signal generated by distribution in the 90-degree lagging phase are generated. A phase difference between the emission light and the reflected light can be detected by the modulation signals in the phases different from each other by 90 degrees. With this phase difference, it is possible to clock the time of flight from the light source 3 to the imaging element 10 via the object. Details of the detection of the phase difference will be described later.

Note that a frequency of the pulse train of the emission light from the light source 3 is equal to a frequency of the distribution in the pixel 100 (reciprocal of the period from T3 to T5 in FIG. 11). Hereinafter, this frequency is referred to as a modulation frequency. Ranging processing needs to be performed at a plurality of modulation frequencies. This is because an optimal modulation frequency in the ranging changes according to a distance to the object. Ranging accuracy is improved as the modulation frequency becomes higher. On the other hand, when the modulation frequency is high, a measurable distance becomes short. This is because it is difficult to clock the time of flight exceeding a cycle of the modulation frequency.

In such a manner, the common transfer control is performed in the vertical drive unit 30, and the electric charges generated by the photoelectric conversion units 101 and 102 are distributed, whereby the modulated image signals can be acquired. The ranging by the ToF method becomes possible.

[Ranging Processing by Phase Difference Detection Method]

FIG. 12 is a view illustrating an example of ranging processing by phase difference detection according to the embodiment of the present disclosure. The drawing is a view illustrating an example of a processing procedure of ranging by phase difference detection (S110).

First, image signals are generated by the individual transfer control (Step S111). This can be performed when the vertical drive unit 30 outputs a control signal of the individual transfer control to the pixel 100. As a result, phase difference signals that are image signals for detecting a phase difference are generated.

Then, the image processing unit 50 described in FIG. 2 performs image processing on the generated image signals (phase difference signals) (Step S112). As this image processing, for example, noise reduction processing can be performed.

Then, the ranging unit 60 detects a phase difference of the incident light on the basis of the image signals (phase difference signals) after the image processing (Step S113).

Then, the ranging unit 60 detects a focal position of the object on the basis of the detected phase difference, and detects a distance to the object (Step S114). With the above processing, the ranging by the phase difference detection can be performed.

[Ranging Processing by ToF Method]

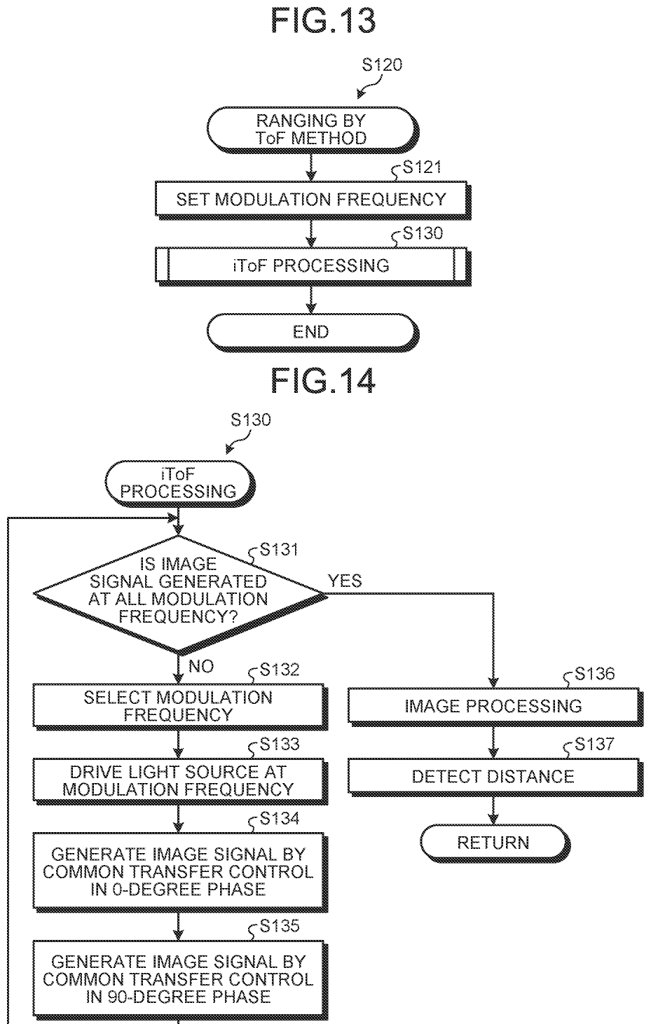

FIG. 13 is a view illustrating an example of the ranging processing by the ToF method according to the embodiment of the present disclosure. The drawing is a view illustrating an example of a processing procedure of the ranging by the ToF method (S120).

First, a modulation frequency is set (Step S121). This is performed, for example, by the control device 2 described in FIG. 1. As the modulation frequency, for example, a plurality of frequencies such as 10 MHz and 100 MHz can be set.

Then, iToF processing (Step S130) is performed and the distance is measured.

[iToF Processing]

FIG. 14 is a view illustrating an example of the iToF processing according to the embodiment of the present disclosure. The drawing is a view illustrating the processing of Step S130 in FIG. 13.

First, the control device 2 determines whether image signals are generated at all the modulation frequencies (Step S131). Specifically, it is determined whether emission of light from the light source 3 and generation of an image signal in the imaging element 10 (modulation of reflected light) at all frequencies set in the processing of Step S121 in FIG. 13 are ended. As a result, in a case where the image signals are not generated at all the modulation frequencies (Step S131, No), a modulation frequency is selected (Step S132), and the light source 3 is driven at the selected modulation frequency (Step S133).

Then, an image signal is generated by the common transfer control in the 0-degree phase (Step S134). This can be performed when the vertical drive unit 30 outputs a control signal of the common transfer control to the pixel 100.

Then, an image signal is generated by the common transfer control in the 90-degree phase (Step S135), and the processing returns to Step S131.

In Step S131, in a case where the image signals are generated at all the modulation frequencies (Step S131, Yes), the image processing unit 50 performs image processing on the generated image signals (Step S136).

Then, the ranging unit 60 detects the time of flight on the basis of the image signals after the image processing, and detects the distance to the object (Step S137).

[Ranging Processing by Phase Difference Detection

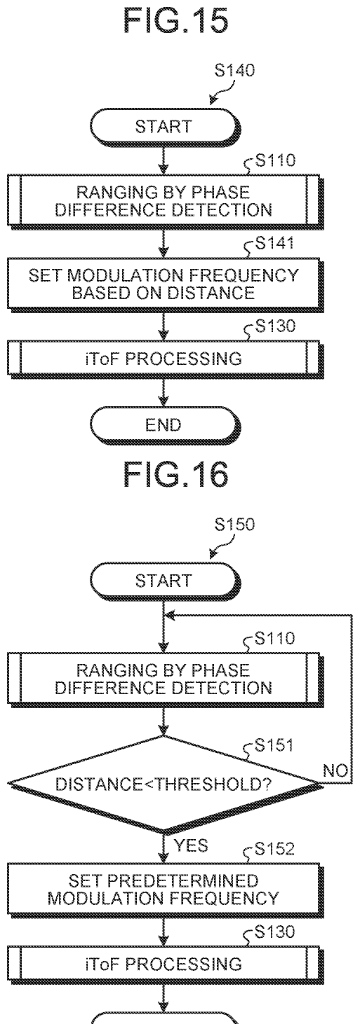

Method and ToF Method]FIG. 15 is a view illustrating an example of the ranging processing by the phase difference detection method and the ToF method according to the embodiment of the present disclosure. The drawing is a view illustrating the ranging processing in which the phase difference detection method and the ToF method are combined (S140).

First, the ranging by the phase difference detection described in FIG. 12 (S110) is performed. From this, a distance of the object is measured.

Then, a modulation frequency is set on the basis of the measured distance (Step S141). A modulation frequency corresponding to the distance is set.

Then, the iToF processing described in FIG. 14 (S130) is performed, and the distance measurement by the ToF method is performed.

From the above processing, the ranging by the phase difference detection method and the ToF method can be performed. The distance of the object is measured at high speed by the phase difference detection method, and the measurement with high accuracy is performed by the ToF method. For example, acquisition of a surface shape of the object, or the like can be performed by the ToF method. Since the distance of the object is acquired by the phase difference detection method, a modulation frequency corresponding to this distance can be set in Step S141. Unlike Step S121 in FIG. 13, the modulation frequencies to be set can be reduced. It is also possible to set a single modulation frequency that is optimal for the distance measured by the phase difference detection method. Since the iToF processing is performed at few modulation frequencies, processing time of the ranging by the ToF method can be shortened.

FIG. 16 is a view illustrating another example of ranging processing by the phase difference detection method and the ToF method according to the embodiment of the present disclosure. Similarly to FIG. 15, the drawing is a view illustrating the ranging processing in which the phase difference detection method and the ToF method are combined. There is a difference from the processing of FIG. 15 in a point that the ToF processing is performed in a case where the object becomes closer.

First, the ranging processing by the phase difference detection (S110) is performed. From this, a distance of the object is measured.

Then, it is determined whether a distance to the object is shorter than a threshold (Step S151). As a result, in a case where the distance to the object is equal to or longer than the threshold (Step S151, No), the processing of Step S110 is performed again. On the other hand, in a case where the distance to the object is shorter than the threshold (Step S151, Yes), a predetermined modulation frequency is set (Step S152). This can be performed, for example, when a frequency corresponding to the threshold in Step S151 is set as a predetermined frequency.

Then, the iToF processing (S130) is performed, and the distance measurement by the iToF is performed. Note that it is also possible to wait for a predetermined period when the processing transitions from the processing of Step S151 to Step S110.

By the above processing, it is possible to perform the ranging by the phase difference detection method and to perform switching to the ranging by the ToF method in a case where the object becomes closer than a predetermined distance. The ranging by the iToF has a problem that a measurable distance is short while high accuracy is acquired. Thus, the ranging by the phase difference detection method is repeatedly performed at regular intervals, and the processing of performing switching to the ranging by the iToF is performed in a case where the object becomes closer. This makes it possible to perform the ranging according to the distance of the object.

A ranging device that performs this ranging processing can be used for an in-vehicle device or the like, for example. Application to processing in which the ranging by the phase difference detection method is generally performed and accurate inter-vehicle distance is acquired by the iToF in a case where the inter-vehicle distance from a preceding vehicle becomes shorter than a predetermined threshold can be performed.

As described above, the imaging element 10 of the first embodiment of the present disclosure includes the two photoelectric conversion units (photoelectric conversion units 101 and 102) and the two electric charge holding units (first electric charge holding unit 107 and second electric charge holding unit 108) in each of the pixels 100. Furthermore, the pixel 100 further includes the electric charge transfer units 111 to 114 that transfer the electric charges of the two photoelectric conversion units to the two electric charge holding. It is possible to generate a pair of phase difference signals by using the two photoelectric conversion units 101 and 102 as the pair of pupil-divided photoelectric conversion units for the phase difference detection, and to generate an image signal for the ToF by commonly transferring the electric charges generated by the two photoelectric conversion units to any of the two electric charge holding units. As described above, the pixel 100 of the first embodiment of the present disclosure uses the two photoelectric conversion units and the two electric charge holding units for both generation of phase difference signals for the phase difference detection and generation of image signals for the ToF. As a result, the configuration of the pixel 100 of the imaging element 10 that performs the ranging by the phase difference detection method and the ToF method can be simplified.

[Modification Example of the First Embodiment]

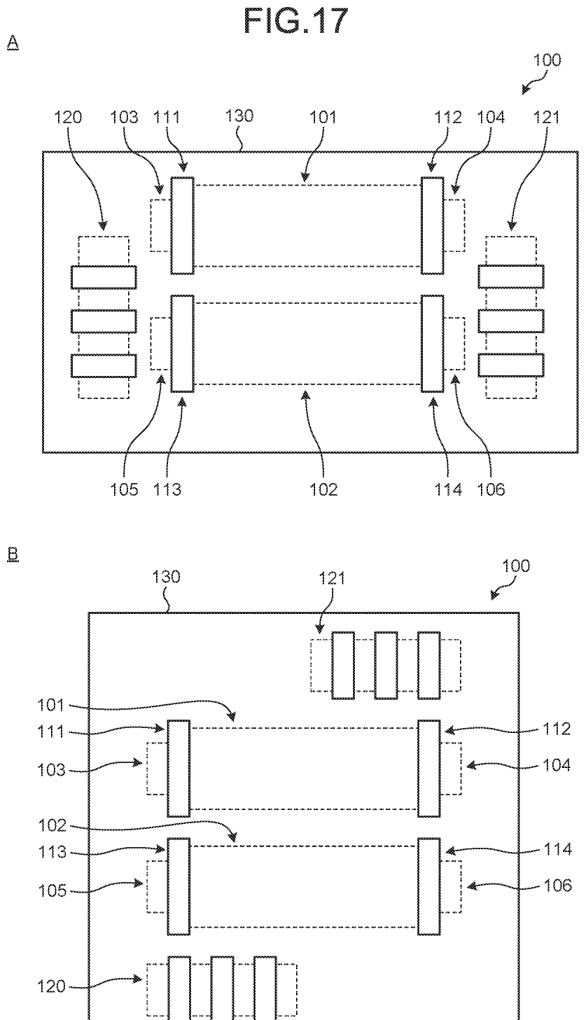

FIG. 17 is a plan view illustrating a modification example of a pixel according to the first embodiment of the present disclosure. Similarly to FIG. 5, the drawing is a plan view illustrating a configuration example of a pixel 100. There is a difference from the pixel 100 in FIG. 5 in a point that arrangement of signal generation units 120 and 121 is different. For the sake of convenience, a part of description of reference signs in the drawing is omitted.

A of the drawing is a view illustrating an example in which a signal generation unit 120 is arranged on a left side of photoelectric conversion units 101 and 102 and a signal generation unit 121 is arranged on a right side thereof.

B of the drawing is a view illustrating an example in which signal generation units 120 and 121 are arranged symmetrically with respect to a center of the pixel 100.

In the pixel 100, the signal generation units 120 and 121 can be arranged at arbitrary positions. Furthermore, an arrangement in which in the photoelectric conversion units 101 and 102 are rotated by 90 degrees can be employed in the pixel 100 in the drawing or in FIG. 5. As a result, it is possible to arrange a pixel 100 including the photoelectric conversion units 101 and 102 pupil-divided in a direction different from that of the pixel 100 in the drawing or FIG. 5. Furthermore, an arrangement being rotated vertically or horizontally may be employed as a configuration of the pixel 100 in the drawing or in FIG. 5. Furthermore, a configuration in which signal generation units 120 and 121 are shared by adjacent pixels 100 can be employed.

### 2. Second Embodiment

The pixel 100 according to the first embodiment described above includes the two photoelectric conversion units (photoelectric conversion units 101 and 102). On the other hand, a pixel 100 according to the second embodiment of the present disclosure is different from the pixel 100 according to the first embodiment in a point of further including an electric charge discharging unit that discharges electric charges of two photoelectric conversion units.

[Configuration of Pixel]

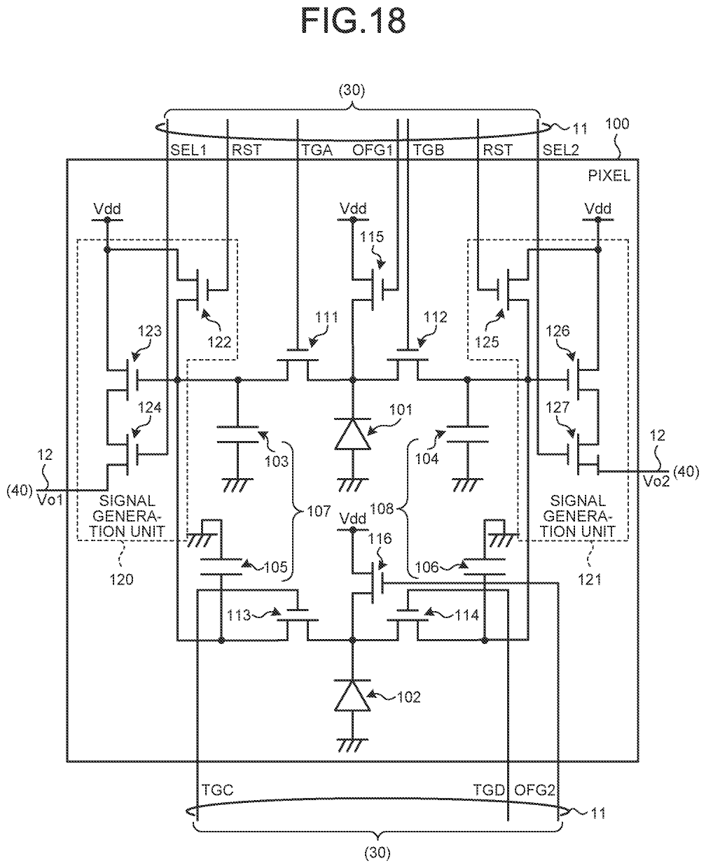

FIG. 18 is a view illustrating a configuration example of a pixel according to the second embodiment of the present disclosure. Similarly to FIG. 3, the drawing is a circuit diagram illustrating a configuration example of a pixel 100. There is a difference from the pixel 100 in FIG. 3 in a point that electric charge discharging units 115 and 116 are further included. In addition, overflow gate signal lines OFG1 and OFG2 are further arranged in a signal line 12 in the drawing.

The electric charge discharging units 115 and 116 discharge the electric charges of the photoelectric conversion units. For the electric charge discharging units 115 and 116, n-channel MOS transistors can be used. A drain of the electric charge discharging unit 115 is connected to a power line Vdd, and a source thereof is connected to a cathode of a photoelectric conversion unit 101. A drain of the electric charge discharging unit 116 is connected to the power line Vdd, and a source thereof is connected to a cathode of a photoelectric conversion unit 102. A gate of the electric charge discharging unit 115 is connected to the overflow gate signal line OFG1, and a gate of the electric charge discharging unit 116 is connected to the overflow gate signal line OFG2. The electric charge discharging units 115 and 116 are controlled by control signals from the overflow gate signal lines OFG1 and OFG2, and can discharge the electric charges of the photoelectric conversion units 101 and 102 to the power line Vdd when becoming the conductive state.

In a period in which the electric charges generated by photoelectric conversion by the photoelectric conversion units 101 and 102 are transferred to an electric charge holding unit 103 and the like and image signals are generated by a signal generation unit 120 and the like, the electric charge discharging units 115 and 116 discharge the electric charges of the photoelectric conversion units 101 and 102. As a result, unnecessary electric charges can be reduced.

[Configuration of Plane of Pixel]

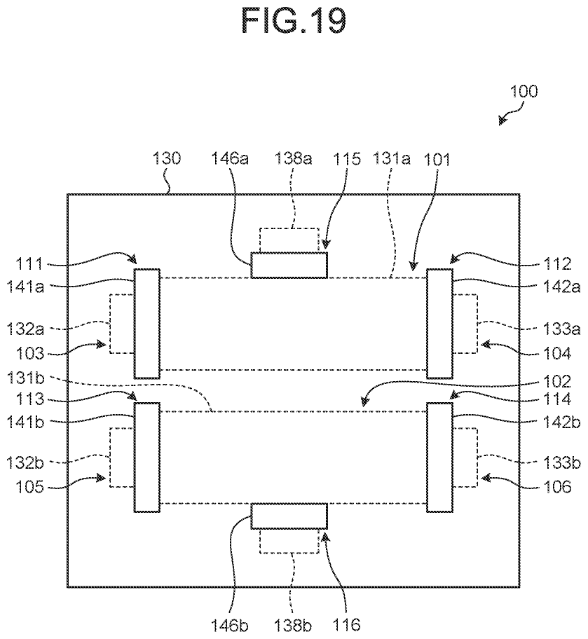

FIG. 19 is a plan view illustrating a configuration example of the pixel according to the second embodiment of the present disclosure. Similarly to FIG. 5, the drawing is a plan view illustrating a configuration example of a pixel 100. There is a difference from the pixel 100 in FIG. 5 in a point that the electric charge discharging units 115 and 116 are further arranged. For the sake of convenience, description of signal generation units 120 and 121 is omitted in the drawing, and a part of description of reference signs is omitted.

A gate 146a of the electric charge discharging unit 115 is arranged in a manner of being adjacent to an upper side of an n-type semiconductor region 131a of the photoelectric conversion unit 101 in the drawing. An n-type semiconductor region 138a is arranged in a manner of being adjacent to this gate 146a. The electric charge discharging unit 115 is a MOS transistor having the n-type semiconductor region 131a and the n-type semiconductor region 138a as a source region and a drain region, respectively. In addition, a gate 146b of the electric charge discharging unit 116 is arranged in a manner of being adjacent to a lower side of an n-type semiconductor region 131b of the photoelectric conversion unit 102 in the drawing. An n-type semiconductor region 138b is arranged in a manner of being adjacent to this gate 146b. The electric charge discharging unit 116 is a MOS transistor having the n-type semiconductor region 131b and the n-type semiconductor region 138b as a source region and a drain region, respectively.

Since the configuration of the imaging element 10 other than these is similar to the configuration of the imaging element 10 of the first embodiment of the present disclosure, description thereof is omitted.

As described above, the pixel 100 of the second embodiment of the present disclosure further includes the electric charge discharging units 115 and 116, and discharges unnecessary electric charges of the photoelectric conversion units 101 and 102. As a result, noise of the image signal due to the unnecessary electric charges can be reduced.

### 3. Third Embodiment

The pixel 100 according to the first embodiment described above includes the gate arranged in a manner of being adjacent to the front surface side of the semiconductor substrate 130. On the other hand, a pixel 100 of the third embodiment of the present disclosure is different from the pixel 100 of the first embodiment in a point that a gate having a shape buried in a semiconductor substrate 130 is included.

[Configuration of Cross-Section of Pixel]

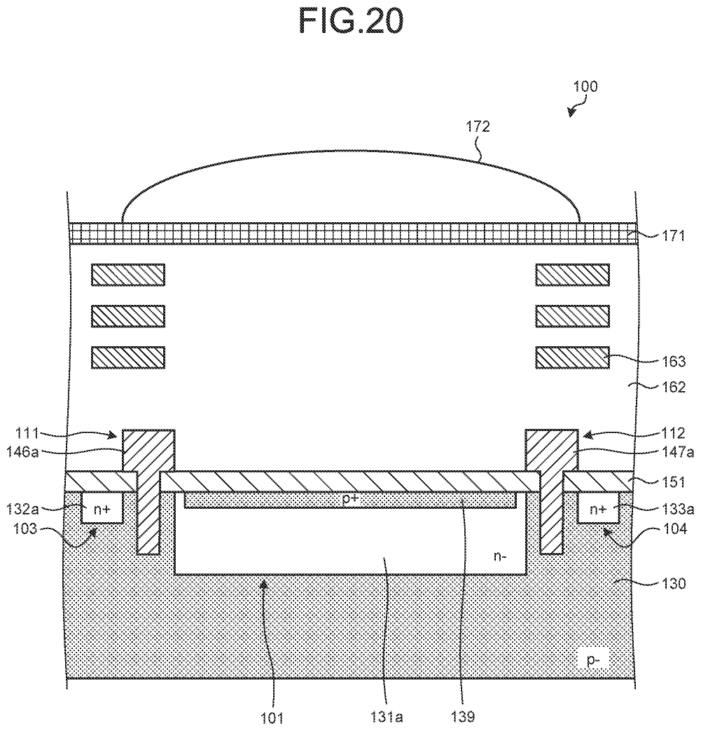

FIG. 20 is a cross-sectional view illustrating a configuration example of a pixel according to the third embodiment of the present disclosure. Similarly to FIG. 6, the drawing is a cross-sectional view illustrating a configuration example of a pixel 100. There is a difference from the pixel 100 of FIG. 6 in a point that gates 146a and 147a are arranged instead of the gates 141a and 142a of the electric charge transfer units 111 and 112.

The gates 146a and 147a in the drawing are arranged on a front surface side of the semiconductor substrate 130 and are configured in a shape partially buried in a well region. The gate 146a is buried in a well region between n-type semiconductor regions 131a and 132a, and the gate 147a is buried in a well region between n-type semiconductor regions 131a and 133a. A gate having such a shape is referred to as a buried gate. A MOS transistor having the buried gate is referred to as a vertical transistor. In the vertical transistor, a channel is formed at an interface between the buried gate and the well region, and electric charges can be also transferred in a thickness direction of the semiconductor substrate 130. By arrangement of the buried gate, a distance between the n-type semiconductor region 131a and the n-type semiconductor region 132a and the like is shortened, and electric charge transfer efficiency can be improved.

Since the configuration of the imaging element 10 other than these is similar to the configuration of the imaging element 10 of the first embodiment of the present disclosure, description thereof is omitted.

As described above, the pixel 100 of the third embodiment of the present disclosure can improve the electric charge transfer efficiency by applying the vertical transistor to an electric charge transfer unit 111 and the like. Time required for an electric charge transfer can be shortened, and speed of generation of an image signal can be increased.

### 4. Fourth Embodiment

The imaging element 10 according to the third embodiment described above is configured as a front-illuminated imaging element. On the other hand, an imaging element 10 of the fourth embodiment of the present disclosure is different from the imaging element 10 of the third embodiment in a point that a back-illuminated imaging element is included.

[Configuration of Cross-Section of Pixel]

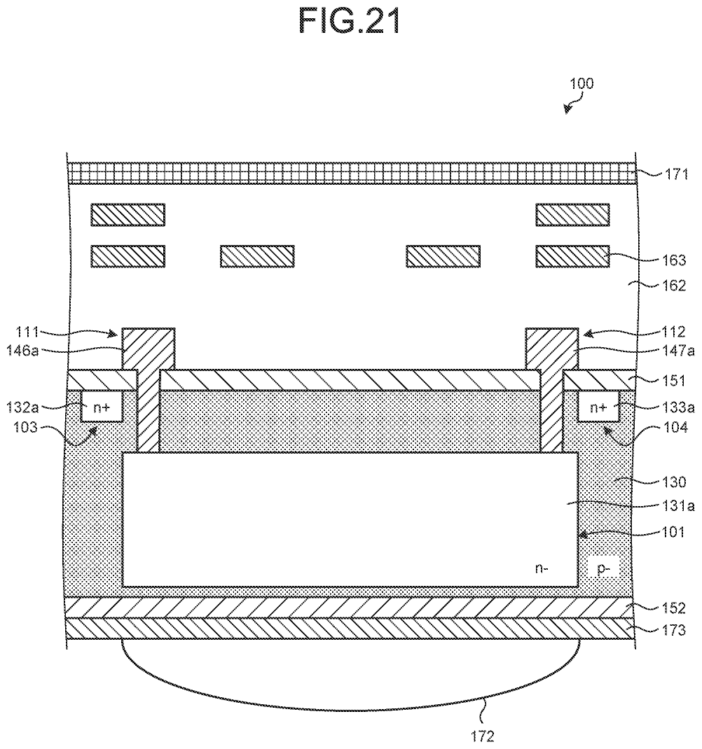

FIG. 21 is a cross-sectional view illustrating a configuration example of a pixel according to the fourth embodiment of the present disclosure. Similarly to FIG. 20, the drawing is a cross-sectional view illustrating a configuration example of a pixel 100. There is a difference from the pixel 100 in FIG. 20 in a point that an n-type semiconductor region 131a of the photoelectric conversion unit 101 is formed in a deep region in the vicinity of a back surface side of a semiconductor substrate 130 and an on-chip lens 172 is arranged on the back surface side of the semiconductor substrate 130.

An insulating film 152 and a protective film 173 are further arranged in the pixel 100 in the drawing. The insulating film 152 is arranged in a manner of being adjacent to a surface on the back surface side of the semiconductor substrate 130 and insulates the back surface side of the semiconductor substrate 130. This insulating film 152 can include, for example, an insulator such as SiO₂. Furthermore, the protective film 173 is arranged between the insulating film 152 and the on-chip lens 172, and protects the back surface side of the semiconductor substrate 130. This protective film 173 can include, for example, the same material as the on-chip lens 172.

The n-type semiconductor region 131a of the photoelectric conversion unit 101 is formed in the vicinity of the back surface side of the semiconductor substrate 130, and is arranged at a position in contact with bottom positions of gates 146a and 147a of electric charge transfer units 111 and 112. Incident light is emitted to the back surface side of the semiconductor substrate 130 via the on-chip lens 172. Electric charges generated by photoelectric conversion of this incident light are accumulated in the n-type semiconductor region 131a of the photoelectric conversion unit 101, and are transferred to electric charge holding units 103 and 104 arranged on a front surface side of the semiconductor substrate 130 by a channel formed at an interface between the gates 146a and 147a. Unlike the front-illuminated imaging element, the incident light is emitted to the photoelectric conversion unit 101 without passing through a wiring region. Thus, sensitivity can be improved in the back-illuminated imaging element.

Since the configuration of the imaging element 10 other than these is similar to the configuration of the imaging element 10 of the first embodiment of the present disclosure, description thereof is omitted.

As described above, the imaging element 10 of the fourth embodiment of the present disclosure includes the back-illuminated imaging element, and can improve sensitivity.

Note that the configuration of the second embodiment can be applied to other embodiments. Specifically, the electric charge discharging units 115 and 116 of FIG. 18 can be applied to the pixels 100 of FIGS. 20 and 21.

### 5. Ranging by Phase Difference Detection

The ranging by the phase difference detection of incident light from a subject which ranging is used in the above-described imaging element 10 will be described.

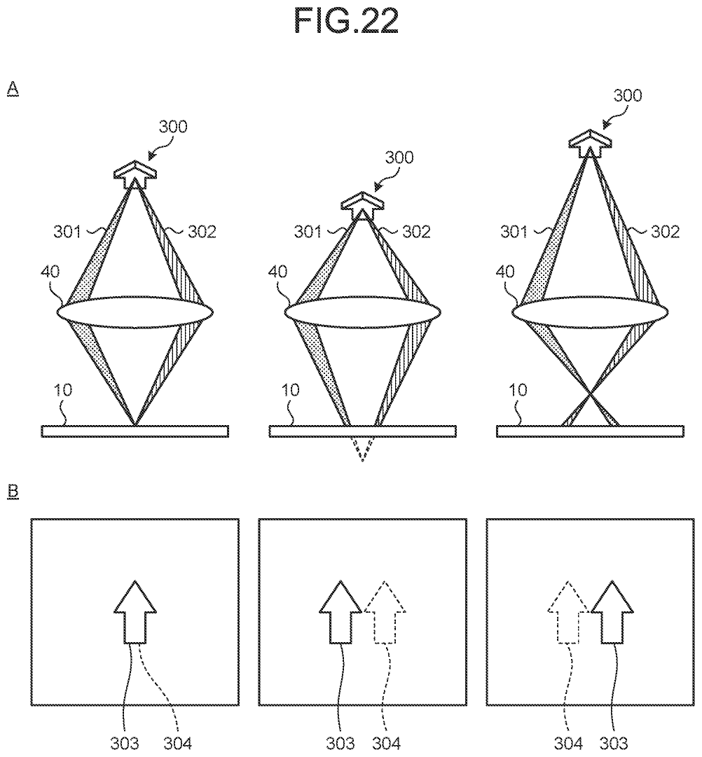

FIG. 22 is a view for describing the phase difference detection according to the embodiment of the present disclosure. A in the drawing is a view illustrating a relationship between positions of a subject 300, a photographing lens 4, and the imaging element 10 and an optical path of incident light. In the drawing, pieces of light passing through a left side and a right side of the photographing lens 4 are respectively represented by 301 and 302. For the sake of convenience, only pieces of light passing through end portions of the photographing lens 4 are illustrated as light 301 and 302. In views on the left, central, and right sides of A in the drawing, a case where a focal position is on (imaging surface of) the imaging element 10 (in-focus state), a case where a focal position is on a side opposite to the subject 300 (so-called back-focus state), and a case where a focal position is on a side of the subject 300 (so-called front-focus state) are respectively illustrated.

B of the drawing is a view illustrating an image of the subject 300 generated by the imaging element 10. In the drawing, a case where photoelectric conversion units 101 and 102 of a pixel 100 are pupil-divided in a lateral direction of the drawing is assumed. By an action of the on-chip lens arranged in the pixel 100, the light 301 passing through the left side of the photographing lens 4 becomes incident on a photoelectric conversion unit arranged on the right side of the pixel 100, and the light 302 passing through the right side of the photographing lens 4 becomes incident on a photoelectric conversion unit arranged on the left side of the pixel 100. An image including an image signal generated on the basis of the photoelectric conversion unit arranged on the right side of the pixel 100 (image 303) and an image including an image signal generated on the basis of the photoelectric conversion unit arranged on the left side (image 304) are generated.

In B of the drawing, images respectively corresponding to the three cases of A in the drawing are illustrated. As illustrated in a left view in B of the drawing, in a case of in-focus, an in-focus image of the subject 300 is generated by the imaging element 10. In this case, the images 303 and 304 are formed in an overlapped manner. On the other hand, in a case of the central and left views of B in the drawing, images having a shape in which the images 303 and 304 are shifted are formed. This image shift represents a phase difference. The images 303 and 304 respectively become images shifted to the left and right in a case of the back-focus state of the central view of B in the drawing, and the images 303 and 304 become images shifted in opposite directions in a case of the front-focus state of the left view of B in the drawing.

In a case of the in-focus state, a relationship between a distance to the subject 300 and the focal position can be expressed by the following expression.

(1/L1)+(1/L2)=1/f

Here, L1 represents a distance from the subject 300 to the photographing lens 4. L2 represents a distance to the focal position. Because of the in-focus state, L2 is a distance between the photographing lens 4 and the imaging surface. f represents a focal length of the photographing lens 4. By calculating L1 on the basis of L2 and f, the distance to the subject 300 (such as value of L1+L2) can be measured. Note that in a case where a phase difference is generated, for example, in the back-focus state, the above expression is corrected by the phase difference.

In such a manner, it is possible to detect the focal position of the subject 300 by detecting the phase difference, and to measure the distance to the subject 300. In addition, it is possible to perform autofocus by adjusting the position of the photographing lens 4 according to the detected focal position.

### 6. Ranging by iToF Method

The ranging by the iToF method used in the imaging element 10 described above will be described.

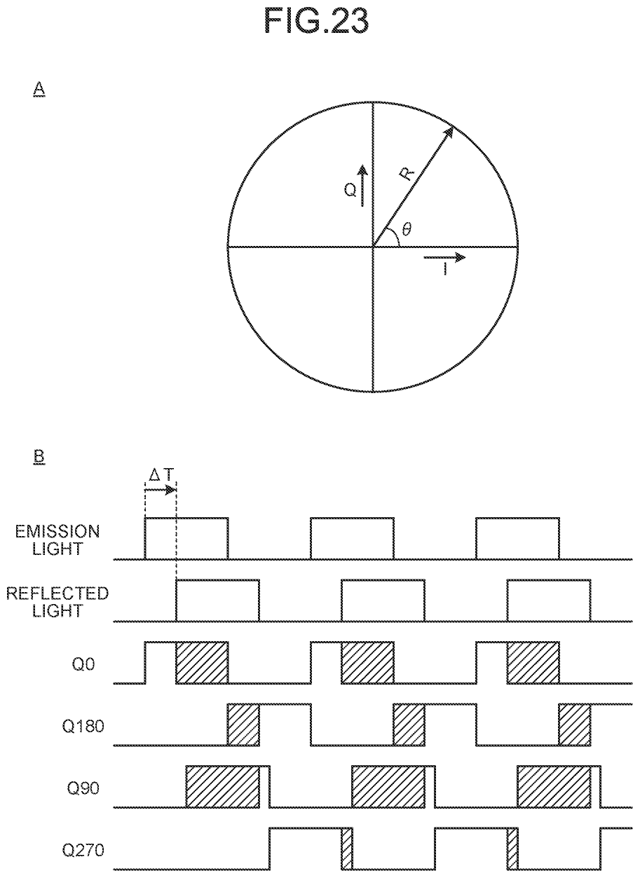

FIG. 23 is a view for describing the iToF method according to the embodiment of the present disclosure. In A of the drawing, a phase of reflected light that is light emitted from a light source 3 and reflected by a subject is illustrated. In A of the drawing, a positive direction of an X axis corresponds to a phase of the emission light. An arrow with “R” represents reflected light. I represents a component, which is in the same phase as the emission light, in the reflected light. Q represents a component, which is orthogonal to the emission light, in the reflected light. A phase difference θ corresponding to the distance is generated in the reflected light R. This phase difference θ can be expressed by the following expression.

θ=arctan(Q/I)

Here, I represents a crest value of the component, which is in the same phase as the emission light, in the reflected light. Q represents a crest value of the component, which is orthogonal to the emission light, in the reflected light. In A of the drawing, sinusoidal emission light and the like is assumed. However, θ can be also calculated for pulse train-shaped emission light and the like by the above expression.

B of the drawing indicates a relationship of the emission light and the reflected light with an exposure period of the pixel 100. The “emission light” and the “reflected light” in A of the drawing respectively represent the emission light from the light source 3 and the reflected light reflected by the subject. An emitted or reflected light flux is represented by a rectangular portion. In such a manner, the emission light becomes pulse train-shaped light with a duty of 50%. The reflected light is pulse train-shaped light delayed by ΔT with respect to the emission light. AT is a delay corresponding to the above-described phase difference θ, and corresponds to a time during which light reciprocates with respect to the subject.

“Q0”, “Q180”, “Q90”, and “Q270” in B of the drawing represent exposure timings in the pixel 100, and a period of a value “1” indicates an exposure period. “Q0”, “Q180”, “Q90”, and “Q270” represent a case where exposure is performed in periods respectively shifted by 0 degrees, 180 degrees, 90 degrees, and 270 degrees from the emission light. A period hatched with oblique lines in B of the drawing corresponds to a period in which the reflected light in the drawing is exposed. I and Q in A of the drawing can be calculated from image signals generated by the four exposures. I and Q can be expressed by the following expressions.

I=Q0−Q180

Q=Q90−Q270

A distance D to the subject can be expressed by the following expression.

D=c×ΔT/2=c×arctan(Q/I)/(4π×f)

Here, c represents a speed of light. f represents a frequency of a pulse train of the emission light. It is possible to calculate the distance D to the subject 300 by substituting the image signals of the exposure in the phases of Q0, Q180, Q90, and Q270 into this expression.

The exposures of Q180 and Q270 respectively have opposite phases with respect to the exposures of Q0 and Q90, and can be performed by distribution of electric charges generated by the photoelectric conversion units 101 and 102. That is, as described in FIG. 14, it is possible to generate image signals of Q0 and Q180 by performing common transfer control on the emission light in the 0-degree phase. Then, it is possible to generate the image signals of Q90 and Q270 by performing the common transfer control in a phase shifted by 90 degrees from the emission light. Note that since subtraction is performed in the process of calculating I and Q, CDS processing described in FIG. 7 and the like is unnecessary.

### Effect

The imaging element 10 includes a first photoelectric conversion unit (photoelectric conversion unit 101) and a second photoelectric conversion unit (photoelectric conversion unit 102) that perform photoelectric conversion of incident light from an object, the first electric charge holding unit 107 and second electric charge holding unit 108 that hold electric charges generated by the photoelectric conversion, a first electric charge transfer unit (electric charge transfer unit 111) that transfers the electric charges generated by the first photoelectric conversion unit (photoelectric conversion unit 101) to the first electric charge holding unit 107, a second electric charge transfer unit (electric charge transfer unit 112) that transfers the electric charges generated by the first photoelectric conversion unit (photoelectric conversion unit 101) to the second electric charge holding unit 108, a third electric charge transfer unit (electric charge transfer unit 113) that transfers the electric charges generated by the second photoelectric conversion unit (photoelectric conversion unit 102) to the first electric charge holding unit 107, a fourth electric charge transfer unit (electric charge transfer unit 114) that transfers the electric charges generated by the second photoelectric conversion unit (photoelectric conversion unit 102) to the second electric charge holding unit 108, and a signal generation unit (signal generation units 120 and 121) that generates an image signal based on the electric charges held in the first electric charge holding unit 107 and an image signal based on the electric charges held in the second electric charge holding unit 108.

As a result, the imaging element 10 can respectively transfer the electric charges respectively generated by the first photoelectric conversion unit (photoelectric conversion unit 101) and the second photoelectric conversion unit (photoelectric conversion unit 102) to the first electric charge holding unit 107 and the second electric charge holding unit 108.

In addition, the imaging element 10 further includes an electric charge transfer control unit (vertical drive unit 30) that controls transfer of the electric charges in the first electric charge transfer unit (electric charge transfer unit 111), the second electric charge transfer unit (electric charge transfer unit 112), the third electric charge transfer unit (electric charge transfer unit 113), and the fourth electric charge transfer unit (electric charge transfer unit 114).

As a result, it is possible to control the transfer of the electric charges in the first electric charge transfer unit (electric charge transfer unit 111), the second electric charge transfer unit (electric charge transfer unit 112), the third electric charge transfer unit (electric charge transfer unit 113), and the fourth electric charge transfer unit (electric charge transfer unit 114).

Furthermore, in the imaging element 10, the electric charge transfer control unit (vertical drive unit 30) performs individual transfer control in which the electric charges respectively generated by the first photoelectric conversion unit (photoelectric conversion unit 101) and the second photoelectric conversion unit (photoelectric conversion unit 102) at the same time are individually transferred to and exclusively held by the first electric charge holding unit 107 and the second electric charge holding unit 108, and common transfer control in which the electric charges respectively generated by the first photoelectric conversion unit (photoelectric conversion unit 101) and the second photoelectric conversion unit (photoelectric conversion unit 101) at the same time are commonly transferred to and collectively held by any of the first electric charge holding unit 107 or the second electric charge holding unit 108 at the same time.

As a result, individual transfer and common transfer of the electric charges respectively generated by the first photoelectric conversion unit (photoelectric conversion unit 101) and the second photoelectric conversion unit (photoelectric conversion unit 102) at the same time can be performed.

Furthermore, in the imaging element 10, the electric charge transfer control unit (vertical drive unit 30) performs the individual transfer control in order to cause the signal generation unit to generate two image signals for detecting a phase difference of the incident light.

As a result, the imaging element 10 can detect the phase difference of the incident light.

Furthermore, in the imaging element 10, the electric charge transfer control unit (vertical drive unit 30) alternately distributes the electric charges simultaneously generated in the first photoelectric conversion unit (photoelectric conversion unit 101) and the second photoelectric conversion unit (photoelectric conversion unit 102) to the first electric charge holding unit 107 and the second electric charge holding unit 108, and performs the common transfer control to cause the signal generation unit (signal generation units 120 and 121) to generate two image signals based on the distributed electric charges.

As a result, it is possible to generate the image signals based on the electric charges generated by the photoelectric conversion and alternately distributed.

Furthermore, in the imaging element 10, the electric charge transfer control unit (vertical drive unit 30) performs control to make any of the first electric charge transfer unit (electric charge transfer unit 111) and the fourth electric charge transfer unit (electric charge transfer unit 114) or the second electric charge transfer unit (electric charge transfer unit 112) and the third electric charge transfer unit (electric charge transfer unit 113) conductive at the same time in the individual transfer control.

As a result, the imaging element 10 can perform the individual transfer control.

Furthermore, in the imaging element 10, the electric charge transfer control unit (vertical drive unit 30) performs control to make any of the first electric charge transfer unit (electric charge transfer unit 111) and the third electric charge transfer unit (electric charge transfer unit 113) or the second electric charge transfer unit (electric charge transfer unit 112) and the fourth electric charge transfer unit (electric charge transfer unit 114) conductive in different periods in the individual transfer control.

As a result, the imaging element 10 can perform the individual transfer control.

Furthermore, in the imaging element 10, the electric charge transfer control unit performs control to make any of the first electric charge transfer unit and the third charge transfer unit or the second electric charge transfer unit and the fourth electric charge transfer unit conductive at the same time in the common transfer control.

As a result, the imaging element 10 can perform the common transfer control.

Furthermore, the imaging element 10 further includes the ranging unit 60 that performs ranging processing of measuring a distance to the object on the basis of the generated two image signals.

As a result, the imaging element 10 can perform the ranging processing.

Furthermore, in the imaging element 10, the ranging unit 60 performs, as the ranging processing, processing of detecting a phase difference of the incident light on the basis of the two image signals generated on the basis of the respective electric charges transferred by the individual transfer control and held in the first electric charge holding unit 107 and the second electric charge holding unit 108, and of measuring a distance to the object on the basis of the detected phase difference.

As a result, the imaging element 10 can measure the distance to the object on the basis of the phase difference of the incident light.

Furthermore, in the imaging element 10, the ranging unit 60 can perform, as the ranging processing, processing in which the respective electric charges generated by the first photoelectric conversion unit (photoelectric conversion unit 101) and the second photoelectric conversion unit (photoelectric conversion unit 102) on the basis of the reflected light emitted as pulse train-shaped light in a predetermined cycle from the light source 3 and reflected by the object are transferred by the common transfer control and held by the first electric charge holding unit 107 and the second electric charge holding unit 108 and the distance to the object is measured on the basis of the two image signals generated on the basis of the held respective electric charges.

As a result, it is possible to measure the distance to the object by the iToF.

Furthermore, the imaging element 10 further includes a first electric charge discharging unit (electric charge discharging unit 115) and a second electric charge discharging unit (electric charge discharging unit 116) that respectively discharge the electric charges of the first photoelectric conversion unit (photoelectric conversion unit 101) and the second photoelectric conversion unit (photoelectric conversion unit 102).

As a result, unnecessary electric charges of the first photoelectric conversion unit (photoelectric conversion unit 101) and the second photoelectric conversion unit (photoelectric conversion unit 102) can be discharged.

The imaging device 1 includes the light source 3 that emits light to an object, a first photoelectric conversion unit (photoelectric conversion unit 101) and a second photoelectric conversion unit (photoelectric conversion unit 102) that perform photoelectric conversion of emitted incident light reflected by the object, the first electric charge holding unit 107 and second electric charge holding unit 108 that hold electric charges generated by the photoelectric conversion, a first electric charge transfer unit (electric charge transfer unit 111) that transfers the electric charges generated by the first photoelectric conversion unit (photoelectric conversion unit 101) to the first electric charge holding unit 107, a second electric charge transfer unit (electric charge transfer unit 112) that transfers the electric charges generated by the first photoelectric conversion unit (photoelectric conversion unit 101) to the second electric charge holding unit 108, a third electric charge transfer unit (electric charge transfer unit 113) that transfers the electric charges generated by the second photoelectric conversion unit (photoelectric conversion unit 102) to the first electric charge holding unit 107, a fourth electric charge transfer unit (electric charge transfer unit 114) that transfers the electric charges generated by the second photoelectric conversion unit (photoelectric conversion unit 102) to the second electric charge holding unit 108, and a signal generation unit (signal generation units 120 and 121) that generates an image signal based on the electric charges held in the first electric charge holding unit 107 and an image signal based on the electric charges held in the second electric charge holding unit 108.

As a result, on the basis of the light emitted from the light source 3 and reflected by the object, the imaging device 1 can respectively transfer the electric charges respectively generated by the first photoelectric conversion unit (photoelectric conversion unit 101) and the second photoelectric conversion unit (photoelectric conversion unit 102) to the first electric charge holding unit 107 and the second electric charge holding unit 108.

Note that the effects described in the present description are merely examples and are not limitations, and there may be a different effect.

Note that the present technology can also have the following configurations.

(1) An imaging element comprising:

a first photoelectric conversion unit and a second photoelectric conversion unit that perform photoelectric conversion of incident light from an object;

a first electric charge holding unit and a second electric charge holding unit that hold electric charges generated by the photoelectric conversion;

a first electric charge transfer unit that transfers the electric charges generated by the first photoelectric conversion unit to the first electric charge holding unit;

a second electric charge transfer unit that transfers the electric charges generated by the first photoelectric conversion unit to the second electric charge holding unit;

a third electric charge transfer unit that transfers the electric charges generated by the second photoelectric conversion unit to the first electric charge holding unit;

a fourth electric charge transfer unit that transfers the electric charges generated by the second photoelectric conversion unit to the second electric charge holding unit; and

a signal generation unit that generates an image signal based on the electric charges held in the first electric charge holding unit and an image signal based on the electric charges held in the second electric charge holding unit.

(2) The imaging element according to the above (1), further comprising an electric charge transfer control unit that controls the transfer of the electric charges in the first electric charge transfer unit, the second electric charge transfer unit, the third electric charge transfer unit, and the fourth electric charge transfer unit.
(3) The imaging element according to the above (2), wherein the electric charge transfer control unit performs individual transfer control in which the electric charges respectively generated by the first photoelectric conversion unit and the second photoelectric conversion unit at a same time are individually transferred to and exclusively held by the first electric charge holding unit and the second electric charge holding unit, and common transfer control in which the electric charges respectively generated by the first photoelectric conversion unit and the second photoelectric conversion unit at a same time are commonly transferred to and collectively held by any of the first electric charge holding unit or the second electric charge holding unit at a same time.
(4) The imaging element according to the above (3), wherein the electric charge transfer control unit performs the individual transfer control to cause the signal generation unit to generate the image signals for detecting a phase difference of the incident light.
(5) The imaging element according to the above (3), wherein the electric charge transfer control unit alternately distributes the electric charges simultaneously generated in the first photoelectric conversion unit and the second photoelectric conversion unit to the first electric charge holding unit and the second electric charge holding unit, and performs the common transfer control to cause the signal generation unit to generate the image signals based on the distributed electric charges.
(6) The imaging element according to the above (3), wherein the electric charge transfer control unit performs control of making any of the first electric charge transfer unit and the fourth electric charge transfer unit or the second electric charge transfer unit and the third electric charge transfer unit conductive at the same time in the individual transfer control.
(7) The imaging element according to the above (3), wherein the electric charge transfer control unit performs control of making any of the first electric charge transfer unit and the third electric charge transfer unit or the second electric charge transfer unit and the fourth electric charge transfer unit conductive in different periods in the individual transfer control.
(8) The imaging element according to the above (3), wherein the electric charge transfer control unit performs control of making any of the first electric charge transfer unit and the third electric charge transfer unit or the second electric charge transfer unit and the fourth electric charge transfer unit conductive at the same time in the common transfer control.
(9) The imaging element according to the above (3), further comprising a ranging unit that performs ranging processing of measuring a distance to the object on a basis of the generated image signals.
(10) The imaging element according to the above (9), wherein the ranging unit performs, as the ranging processing, processing of detecting a phase difference of the incident light on a basis of the image signals generated on a basis of the respective electric charges transferred by the individual transfer control and held in the first electric charge holding unit and the second electric charge holding unit, and of measuring the distance to the object on a basis of the detected phase difference.
(11) The imaging element according to the above (9), wherein the ranging unit performs, as the ranging processing, processing in which the respective electric charges generated by the first photoelectric conversion unit and the second photoelectric conversion unit on a basis of reflected light emitted as pulse train-shaped light in a predetermined cycle from the light source and reflected by the object are transferred by the common transfer control and held in the first electric charge holding unit and the second electric charge holding unit and the distance to the object is measured on a basis of the image signals generated on a basis of the held respective electric charges.
(12) The imaging element according to any one of the above (1) to (11), further comprising a first electric charge discharging unit and a second electric charge discharging unit that respectively discharge the electric charges of the first photoelectric conversion unit and the second photoelectric conversion unit.
(13) An imaging device comprising:

a light source that emits light to an object;

a first photoelectric conversion unit and a second photoelectric conversion unit that perform photoelectric conversion of emitted incident light reflected by the object;

a first electric charge holding unit and a second electric charge holding unit that hold electric charges generated by the photoelectric conversion;

a first electric charge transfer unit that transfers the electric charges generated by the first photoelectric conversion unit to the first electric charge holding unit;

a second electric charge transfer unit that transfers the electric charges generated by the first photoelectric conversion unit to the second electric charge holding unit;

a third electric charge transfer unit that transfers the electric charges generated by the second photoelectric conversion unit to the first electric charge holding unit;

a fourth electric charge transfer unit that transfers the electric charges generated by the second photoelectric conversion unit to the second electric charge holding unit; and

a signal generation unit that generates an image signal based on the electric charges held in the first electric charge holding unit and an image signal based on the electric charges held in the second electric charges holding unit.

### REFERENCE SIGNS LIST

1 IMAGING DEVICE
3 LIGHT SOURCE
10 IMAGING ELEMENT
20 PIXEL ARRAY UNIT
30 VERTICAL DRIVE UNIT
40 COLUMN SIGNAL PROCESSING UNIT
60 RANGING UNIT
100 PIXEL
101, 102 PHOTOELECTRIC CONVERSION UNIT
103 to 106 ELECTRIC CHARGE HOLDING UNIT
107 FIRST ELECTRIC CHARGE HOLDING UNIT
108 SECOND ELECTRIC CHARGE HOLDING UNIT
111 to 114 ELECTRIC CHARGE TRANSFER UNIT
115, 116 ELECTRIC CHARGE DISCHARGING UNIT
120, 121 SIGNAL GENERATION UNIT

1. An imaging element comprising:
a first photoelectric conversion unit and a second photoelectric conversion unit that perform photoelectric conversion of incident light from an object;
a first electric charge holding unit and a second electric charge holding unit that hold electric charges generated by the photoelectric conversion;
a first electric charge transfer unit that transfers the electric charges generated by the first photoelectric conversion unit to the first electric charge holding unit;
a second electric charge transfer unit that transfers the electric charges generated by the first photoelectric conversion unit to the second electric charge holding unit;
a third electric charge transfer unit that transfers the electric charges generated by the second photoelectric conversion unit to the first electric charge holding unit;
a fourth electric charge transfer unit that transfers the electric charges generated by the second photoelectric conversion unit to the second electric charge holding unit; and
a signal generation unit that generates an image signal based on the electric charges held in the first electric charge holding unit and an image signal based on the electric charges held in the second electric charge holding unit.

2. The imaging element according to claim 1, further comprising an electric charge transfer control unit that controls the transfer of the electric charges in the first electric charge transfer unit, the second electric charge transfer unit, the third electric charge transfer unit, and the fourth electric charge transfer unit.

3. The imaging element according to claim 2, wherein the electric charge transfer control unit performs individual transfer control in which the electric charges respectively generated by the first photoelectric conversion unit and the second photoelectric conversion unit at a same time are individually transferred to and exclusively held by the first electric charge holding unit and the second electric charge holding unit, and common transfer control in which the electric charges respectively generated by the first photoelectric conversion unit and the second photoelectric conversion unit at a same time are commonly transferred to and collectively held by any of the first electric charge holding unit or the second electric charge holding unit at a same time.

4. The imaging element according to claim 3, wherein the electric charge transfer control unit performs the individual transfer control to cause the signal generation unit to generate the image signals for detecting a phase difference of the incident light.

5. The imaging element according to claim 3, wherein the electric charge transfer control unit alternately distributes the electric charges simultaneously generated in the first photoelectric conversion unit and the second photoelectric conversion unit to the first electric charge holding unit and the second electric charge holding unit, and performs the common transfer control to cause the signal generation unit to generate the image signals based on the distributed electric charges.

6. The imaging element according to claim 3, wherein the electric charge transfer control unit performs control of making any of the first electric charge transfer unit and the fourth electric charge transfer unit or the second electric charge transfer unit and the third electric charge transfer unit conductive at the same time in the individual transfer control.

7. The imaging element according to claim 3, wherein the electric charge transfer control unit performs control of making any of the first electric charge transfer unit and the third electric charge transfer unit or the second electric charge transfer unit and the fourth electric charge transfer unit conductive in different periods in the individual transfer control.

8. The imaging element according to claim 3, wherein the electric charge transfer control unit performs control of making any of the first electric charge transfer unit and the third electric charge transfer unit or the second electric charge transfer unit and the fourth electric charge transfer unit conductive at the same time in the common transfer control.

9. The imaging element according to claim 3, further comprising a ranging unit that performs ranging processing of measuring a distance to the object on a basis of the generated image signals.

10. The imaging element according to claim 9, wherein the ranging unit performs, as the ranging processing, processing of detecting a phase difference of the incident light on a basis of the image signals generated on a basis of the respective electric charges transferred by the individual transfer control and held in the first electric charge holding unit and the second electric charge holding unit, and of measuring the distance to the object on a basis of the detected phase difference.

11. The imaging element according to claim 9, wherein the ranging unit performs, as the ranging processing, processing in which the respective electric charges generated by the first photoelectric conversion unit and the second photoelectric conversion unit on a basis of reflected light emitted as pulse train-shaped light in a predetermined cycle from the light source and reflected by the object are transferred by the common transfer control and held in the first electric charge holding unit and the second electric charge holding unit and the distance to the object is measured on a basis of the image signals generated on a basis of the held respective electric charges.

12. The imaging element according to claim 1, further comprising a first electric charge discharging unit and a second electric charge discharging unit that respectively discharge the electric charges of the first photoelectric conversion unit and the second photoelectric conversion unit.

13. An imaging device comprising:
a light source that emits light to an object;
a first photoelectric conversion unit and a second photoelectric conversion unit that perform photoelectric conversion of emitted incident light reflected by the object;
a first electric charge holding unit and a second electric charge holding unit that hold electric charges generated by the photoelectric conversion;
a first electric charge transfer unit that transfers the electric charges generated by the first photoelectric conversion unit to the first electric charge holding unit;
a second electric charge transfer unit that transfers the electric charges generated by the first photoelectric conversion unit to the second electric charge holding unit;
a third electric charge transfer unit that transfers the electric charges generated by the second photoelectric conversion unit to the first electric charge holding unit;
a fourth electric charge transfer unit that transfers the electric charges generated by the second photoelectric conversion unit to the second electric charge holding unit; and
a signal generation unit that generates an image signal based on the electric charges held in the first electric charge holding unit and an image signal based on the electric charges held in the second electric charges holding unit.
